(19) United States
(12) Patent Application Publication
(10) Pub. No.: US 2018/0157120 A1
(43) Pub. Date: Jun. 7, 2018

(54) BACKLIGHT DEVICE AND LIQUID CRYSTAL DISPLAY DEVICE PROVIDED THEREWITH

(71) Applicant: SHARP KABUSHIKI KAISHA, Sakai City, Osaka (JP)

(72) Inventors: AYA OKAMOTO, Sakai City (JP); MAKOTO SHIOMI, Sakai City (JP)

(21) Appl. No.: 15/576,481

(22) PCT Filed: Apr. 15, 2016
(86) PCT No.: PCT/JP2016/062070

§ 371 Date: Nov. 22, 2017

(30) Foreign Application Priority Data
May 25, 2015 (JP) 2015-105128

(51) Int. Cl. G02F 1/1335; H01L 33/50

(52) U.S. Cl. CPC G02F 1/133609; G02F 1/133603; G02F 2001/133612; H01L 33/504; G02F 2001/133614; G02F 1/133611

(57) ABSTRACT

To realize a backlight device capable of adjusting and changing the color temperature without lowering the color purity. The light source constituting the backlight device is composed of:
a first magenta light emitter (60 M1)) having a blue LED element (6 (B)) and a relatively large amount of a red phosphor (7 (R));
a second magenta light emitter (60 (M2)) having a blue LED element (6 (B)) and a relatively small amount of red phosphor (7 (R)); and
a green light emitter (60 (G)) having a green LED element (6 (G)).

The light emission intensity of the first magenta light emitter (60 (M1)), the light emission intensity of the second magenta light emitter (60 (M2)), and the light emission intensity of the green light emitter (60 (G) are independently controlled by the backlight control unit.

### TECHNICAL FIELD

The present invention relates to a backlight device, particularly, to a backlight device for a liquid crystal display device using an LED (light emitting diode) as a light source.

### BACKGROUND ART

In recent years, digital devices have become more sophisticated and have higher performance, and demands for higher quality of various types of images are increasing. Therefore, color reproduction range (also referred to as “color gamut”) has been expanded in the fields of display devices, printing devices, imaging devices, and the like. With respect to liquid crystal display devices such as liquid crystal televisions, for example, backlight devices and color filters have been improved to expand the color reproduction range.

In liquid crystal display devices, colors are displayed by additive color mixing of three primary colors. For this reason, a transmissive liquid crystal display device requires a backlight device capable of irradiating a liquid crystal panel with white light including a red component, a green component, and a blue component. In the related art, cold cathode tubes called CCFLs have been widely adopted as the light source of the backlight device. In recent years, however, the adoption of LEDs has been increasing from the perspective of low power consumption and ease of luminance control.

In general, in addition to a chip state LED (LED element), those in which LED elements (LED chip) are covered with lenses (packaged state) are also called “LEDs”. However, in this specification, in order to clearly distinguish the “LED element” and “the one in which the LED element is covered with lens”, “one in which the LED element is covered with lens” is referred to as a “light emitter.”

As described above, a transmission liquid crystal display device requires a backlight device capable of irradiating a liquid crystal panel with white light. Therefore, for example, a backlight device (see FIG. 39) using a white light emitter 91 having a structure in which a blue LED element 6 (B) is covered with a yellow phosphor 7 (Y) as a light source, a backlight device (see FIG. 40) using a white light emitter 92 having a structure in which the blue LED element 6 (B) is covered with a red phosphor 7 (R) and a green phosphor 7 (G) as a light source, and a backlight device (see FIG. 41) using a white light emitter 93 having a structure in which the ultraviolet LED element 6 (P) is covered with the red phosphor 7 (R), the green phosphor 7 (G), and a blue phosphor 7 (B) as a light source are used. Further, in each of the above configurations, each phosphor is excited by light emitted from a corresponding LED element to emit light. In addition, a backlight device (see FIG. 42) using a red light emitter 94 composed of a red LED element 6 (R), a green light emitter 95 composed of a green LED element 6 (G) and a blue light emitter 96 composed of a blue LED element 6 (B) as a light source may be used in some cases. The configuration illustrated in FIG. 42 is adopted, for example, when a wider color reproduction range is desired.

The appearance of an image displayed on the display device such as the liquid crystal display device or the like changes largely depending on the color temperature (the white color temperature when white is displayed). For this reason, the viewer being capable of selecting a desired color temperature according to the type of video to be viewed is preferable, for example. Generally, a function of adjusting the color temperature is provided in display devices in recent years.

Note, the following related art literature are known in relation to the present invention. JP 2008-283155 A discloses an invention of a light emitting device provided with two or more types of light source modules (each light source module including an LED element and a phosphor) that emit lights of mutually different color temperatures. According to this light emitting device, it is possible to change the color temperature along the blackbody locus (locus of blackbody radiation). Further, JP 2008-205133 A discloses an invention of a backlight device having a configuration in which a small size LED element for color adjustment is incorporated in a light emitter composed of a large size LED element and a phosphor excited to emit light by the light emitted from the LED element. According to this backlight device, it is possible to adjust the color temperature by controlling the luminance of the light emitted from the small size LED element.

### CITATION LIST

### Patent Literature

PTL 1: JP 2008-283155 A

PTL 2: JP 2008-205133 A

### SUMMARY OF INVENTION

### Technical Problem

When the configuration illustrated in FIGS. 39 to 41 is adopted as the configuration of the light source, the luminance control (light emission intensity control) can be performed only for one kind of LED element. For this reason, it is difficult to adjust or change the color temperature using the backlight device. Therefore, in such a case, in order to adjust or change the color temperature, it is necessary to change the color in the liquid crystal panel. Specifically, R, G, B gradation values (luminance values) of the video signal are corrected according to the target color temperature. For example, correction is performed so that the gradation value of one color or two colors of R, G, B is smaller than the original value. When such correction is made, a phenomenon called “gradation skipping,” “coloring” or the like occurs where the luminance decreases. As described above, when the color tone is changed in the liquid crystal panel, desired gradation and luminance cannot be obtained, and the quality of display is lowered.

In the case where the configuration illustrated in FIG. 42 or the configuration disclosed in JP 2008-205133 A is adopted, the color temperature can be adjusted and changed relatively easily. However, since it is necessary to control the luminance for the three kinds of LED elements, the configuration of the driving circuit becomes complicated, resulting in high costs and high power consumption. For the red LED element, the output varies greatly depending on the temperature. For the green LED element, the light emission wavelength may change due to the piezo effect. It is difficult to appropriately control the luminance for the three kinds of LED elements including the red LED element and the green LED element, and reliability is not sufficient.

With regards to the configuration disclosed in JP 2008-283155 A, it is possible to generate light having high color rendering properties close to natural light by constructing a white light source with two or more kinds of light source modules. Therefore, the configuration is suitable for lighting. However, with regard to light obtained by this configuration, the half-value width of the light emission spectrum becomes large. Therefore, the color purity decreases. Therefore, the structure disclosed in JP 2008-283155 A is unsuitable as a backlight for a display device.

Accordingly, an object of the present invention is to realize a backlight device capable of adjusting and changing the color temperature without lowering the color purity. Further, an object of the present invention is to enhance the reliability of such a backlight device.

### Solution to Problem

A first aspect of the present invention, including:

a backlight device using a first type light emitter having a light emitting element and a wavelength conversion element for converting a wavelength of light emitted from the light emitting element, the backlight device including

a plurality of kinds of light emitters including at least two kinds of first type light emitters having the same kind of light emitting elements and having the same kind of wavelength conversion elements of the same kind, wherein

the two or more first type light emitters emit lights having mutually different chromaticities and the plurality of kinds of light emitters are configured so that the light emission intensity of the light emitting element included in each light emitter is controlled independently for each kind of light emitters.

According to a second aspect of the present invention, in the first aspect of the present invention, the plurality of kinds of light emitters are three kinds of light emitters.

According to a third aspect of the present invention, in the second aspect of the present invention, a second type light emitter having only a light emitting element is further used as a light source, and the three kinds of light emitters are composed of two kinds of first type light emitters and one kind of second type light emitters.

According to a fourth aspect of the present invention, in the third aspect of the present invention,

the amount of wavelength conversion element included in a first type light emitter of the two types is adjusted so that chromaticity coordinates corresponding to a target color temperature on an xy chromaticity diagram are within in the range of a triangle connecting chromaticity coordinates of light emitted from each of the three kinds of light emitters.

According to a fifth aspect of the present invention, in the third aspect of the present invention, the amount of wavelength conversion element included in the two kinds of first type light emitters is adjusted so that chromaticity coordinates on a blackbody locus corresponding to a color temperature ranging from 4000 K to 14000 K on an xy chromaticity diagram are within the range of a triangle connecting chromaticity coordinates of light emitted from each of the three kinds of light emitters.

According to a sixth aspect of the present invention, in the third aspect of the present invention, the three kinds of light emitters includes:

a first magenta light emitter including a blue light emitting diode element as a light emitting element, and a relatively large amount of red phosphor as a wavelength converting element;

a second magenta light emitter including a blue light emitting diode element as a light emitting element, and a relatively small amount of red phosphor as a wavelength conversion element; and

a green light emitter having a green light emitting diode element as a light emitting element.

According a seventh aspect of the present invention, in the second aspect of the present invention, the three kinds of light emitters are all first type light emitters.

According to an eighth aspect of the present invention, in the seventh aspect of the present invention, on an xy chromaticity diagram, the amount of wavelength conversion elements included in the three kinds of light emitters is adjusted so that chromaticity coordinates corresponding to a target color temperature are within the range of a triangle connecting chromaticity coordinates of light emitted from each of the three kinds of light emitters.

According to a ninth aspect of the present invention, in the seventh aspect of the present invention, the three kinds of light emitters include:

a first white light emitter including a blue light emitting diode element as a light emitting element, a relatively large amount of red phosphor as a wavelength conversion element, and a relatively small amount of green phosphor as a wavelength conversion element;

a second white light emitter including a blue light emitting diode element as a light emitting element, a relatively small amount of red phosphor as a wavelength conversion element, and a relatively large amount of green phosphor as a wavelength conversion element; and

a third white light emitter including a blue light emitting diode element as a light emitting element, a relatively small amount of red phosphor as a wavelength conversion element, and a relatively small amount of green phosphor as a wavelength conversion element.

According to a tenth aspect of the present invention, in the first aspect of the present invention, the plurality of kinds of light emitters are two kinds of first type light emitters, and

the amount of wavelength conversion elements included in the two kinds of first type of light emitters is adjusted so that chromaticity coordinates corresponding to a target color temperature on an xy chromaticity diagram are positioned on a line segment connecting chromaticity coordinates of light emitted from each of the kinds of first type light emitters.

According to an eleventh aspect of the present invention, in the first aspect of the present invention,

the plurality of kinds of light emitters are two kinds of first type light emitters, and include:

a first white light emitter including a blue light emitting diode element as a light emitting element, and a relatively large amount of yellow phosphor as a wavelength conversion element; and

a second white light emitter including a blue light emitting diode element as a light emitting element, and a relatively small amount of yellow phosphor as a wavelength conversion element.

In a twelfth aspect of the present invention, in the first aspect of the present invention, the plurality of kinds of light emitters are two kinds of first type light emitters, and include:

a first white light emitter including a blue light emitting diode element as a light emitting element, a relatively large amount of red phosphor as a wavelength conversion element, and a relatively large amount of green phosphor as a wavelength conversion element; and

a second white light emitter including a blue light emitting diode element as a light emitting element, a relatively small amount of red phosphor as a wavelength conversion element, and a relatively small amount of green phosphor as a wavelength conversion element.

In a thirteenth aspect of the present invention, in the first aspect of the present invention, the light emitting element is a light emitting diode element or a laser diode element.

According to a fourteenth aspect of the present invention, in the first aspect of the present invention, the light emitting element is a light emitting diode element other than a red light emitting diode element.

According to a fifteenth aspect of the present invention, in the first aspect of the present invention, the wavelength conversion element is a phosphor or a quantum dot.

The sixteenth aspect of the present invention is a liquid crystal display device having a liquid crystal panel including a display unit for displaying an image, the backlight device according to the first aspect of the present invention for irradiating light on a backside of the liquid crystal panel, and a backlight control unit for controlling light emission intensity of the plurality of kinds of light emitters for each kind of light emitter.

### Advantageous Effects of Invention

According to a first aspect of the present invention, the light source is composed of a plurality of kinds of light emitters, and the light emission intensity of the light emitting elements included in each light emitter is controlled independently for each kind of light emitter. Therefore, since the luminance of the light of a plurality of colors can be independently controlled, it is possible to adjust and change the color temperature. Moreover, at least two kinds of light emitters among the plurality of kinds of light emitters have light emitting elements of the same kind and have wavelength conversion elements of the same kind. Regardless of how the light emission intensity of the light emitting element included in each light emitter is controlled, the peak wavelength of the combined light does not change and the color purity does not decrease. Therefore, a backlight device capable of adjusting and changing the color temperature without lowering the color purity is realized.

According to a second aspect of the present invention, the chromaticity coordinates within the range of the triangle connecting the chromaticity coordinates of the three kinds of light emitters can be selected as a white point on the xy chromaticity diagram. For this reason, the white point can be adjusted more suitably.

According to a third aspect of the present invention, effects similar to those of the first aspect of the present invention and the second aspect of the present invention can be obtained.

According to a fourth aspect of the present invention, by controlling the light emission intensity of two kinds of first type light emitters (light emitters including light emitting elements and wavelength conversion elements), it is possible to reliably set the color temperature to a desired color temperature.

According to a fifth aspect of the present invention, the range of color temperatures capable of being set is widened. Further, when the color temperature is set to 6500 K, 9300 K, which are general temperature settings, the probability of occurrence of a light emitter in an unlit state is reduced. Therefore, occurrence of unevenness in luminance is suppressed.

According to a sixth aspect of the present invention, effects similar to those of the first aspect of the present invention and the second aspect of the present invention can be obtained. Further, as a light source, a red light emitting diode element having an output greatly changing according to temperature and a green light emitting diode element having an emission wavelength changing due to a piezo effect are not used. For this reason, luminance can be easily and suitably controlled whereby high reliability can be obtained. Therefore, a highly reliable backlight device capable of adjusting and changing the color temperature without lowering the color purity is realized.

According to a seventh aspect of the present invention, effects similar to those of the first aspect of the present invention and the second aspect of the present invention can be obtained.

According to an eighth aspect of the present invention, by controlling the light emission intensity of three kinds of first type light emitters (the light emitters including the light emitting elements and the wavelength conversion elements), it is possible to reliably set a desired color temperature.

According to a ninth aspect of the present invention, similarly to the sixth aspect of the present invention, a highly reliable backlight device capable of adjusting and changing the color temperature without lowering the color purity is realized.

According to a tenth invention of the present invention, by controlling the light emission intensity of two kinds of first type light emitters (light emitters including light emitting elements and wavelength conversion elements), it is possible to reliably set to a desired color temperature.

According to an eleventh aspect of the present invention, similarly to the sixth aspect of the present invention, a highly reliable backlight device capable of adjusting and changing the color temperature without lowering the color purity is realized

According to the twelfth aspect of the present invention, similarly to the sixth aspect of the present invention, a highly reliable backlight device capable of adjusting and changing the color temperature without lowering the color purity is realized. Further, by adjusting the amounts of red phosphor and green phosphor contained in the first white light emitter and the second white light emitter, it is possible to more precisely adjust and change the color temperature.

According a thirteenth aspect of the present invention, effect similar to the first aspect of the present invention can be obtained.

According to a fourteenth aspect of the present invention, a red light emitting diode element is not used in the light source constituting a backlight device. Since the red light emitting diode element has an output changing largely depending on the temperature, according to the fourteenth aspect of the present invention in which the red light emitting diode element is not used as the light source, reliability is improved and costs are reduced because the light source becomes easy to control. In addition, since the red light emitting diode element has poor emission efficiency, using the red light emitting diode element as the light source can reduce power consumption.

According to the fifteenth aspect of the present invention, effects similar to the first aspect of the present invention can be obtained.

According to the sixteenth aspect of the present invention, a liquid crystal display device capable of adjusting and changing the color temperature without lowering the color purity is realized.

### BRIEF DESCRIPTION OF DRAWINGS

FIG. 1 is a diagram illustrating a configuration of the light source mounted on a LED substrate in the backlight device according to a first embodiment of the present invention.

FIG. 2 is a block diagram illustrating the overall configuration of a liquid crystal display device including the backlight device according to the first embodiment.

FIG. 3 is a diagram illustrating an example of a schematic configuration of a backlight device in the first embodiment.

FIG. 4 is a diagram illustrating an arrangement of light sources on an LED substrate in the first embodiment.

FIG. 5 is a diagram for describing a configuration for controlling the light emission intensity of a light emitter in the first embodiment.

FIG. 6 is a diagram for describing control of the light emission intensity of the light emitter in the first embodiment.

FIG. 7 is an xy chromaticity diagram for describing switching of color temperature in the first embodiment.

FIG. 8 is a diagram illustrating a light emission spectrum of light emitted from the two kinds of magenta light emitters when the light emission intensities of two kinds of magenta light emitters are equalized in the first embodiment.

FIG. 9 is a diagram illustrating a light emission spectrum of light emitted from two kinds of magenta light emitters when the color temperature is set to 6500 K in the first embodiment.

FIG. 10 is a diagram illustrating a light emission spectrum of light emitted from two kinds of magenta light emitters when the color temperature is set to 9300 K in the first embodiment.

FIG. 11 is a diagram for describing the effects of the first embodiment.

FIG. 12 is a diagram for describing the effects of the first embodiment.

FIG. 13 is a xy chromaticity diagram describing the distance between the chromaticity coordinates of a first magenta light emitter and the chromaticity coordinates of a second magenta light emitter in the first modified example of the first embodiment.

FIG. 14 is a diagram illustrating a light emission spectrum of light emitted from the two kinds of magenta light emitters when the light emission intensities of the two kinds of magenta light emitters are equalized in the first modified example of the first embodiment.

FIG. 15 is a diagram illustrating a light emission spectrum of light emitted from two kinds of magenta light emitters when the color temperature is set to 6500 K in the first modified example of the first embodiment.

FIG. 16 is a diagram illustrating the light emission spectrum of light emitted from two kinds of magenta light emitters when the color temperature is set to 9300 K in the first modified example of the first embodiment.

FIG. 17 is a diagram illustrating an arrangement of light sources in a second modified example of the first embodiment.

FIG. 18 is a diagram illustrating an arrangement of light sources in a third modified example of the first embodiment.

FIG. 19 is a diagram illustrating an arrangement of light sources in a fourth modified example of the first embodiment.

FIG. 20 is a diagram illustrating a configuration of the light source mounted on a LED substrate in a fifth modified example of the first embodiment.

FIG. 21 is an xy chromaticity diagram for describing switching of color temperature in the fifth modified example of the first embodiment.

FIG. 22 is a diagram illustrating a configuration of the light source mounted on a LED substrate in a sixth modified example of the first embodiment.

FIG. 23 is a xy chromaticity diagram for describing switching of color temperature in the sixth modified example of the first embodiment.

FIG. 24 is a diagram illustrating a configuration of the light source mounted on a LED substrate in a backlight device according to a second embodiment of the present invention.

FIG. 25 is a xy chromaticity diagram for describing switching of color temperature in the second embodiment.

FIG. 26 is a diagram illustrating a light emission spectrum of light emitted from three kinds of white light emitters when the light emission intensities of the three kinds of white light emitters are equalized in the second embodiment.

FIG. 27 is a diagram illustrating a light emission spectrum of light emitted from three kinds of white light emitters when the color temperature is set to 6500 K in the second embodiment.

FIG. 28 is a diagram illustrating a light emission spectrum of light emitted from three kinds of white light emitters when the color temperature is set to 9300 K in the second embodiment.

FIG. 29 is a diagram illustrating a configuration of the light source mounted on a LED substrate in a backlight device according to a third embodiment of the present invention.

FIG. 30 is a diagram illustrating an arrangement of light sources on a LED substrate in the third embodiment.

FIG. 31 is a xy chromaticity diagram for describing switching of color temperature in the third embodiment.

FIG. 32 is a diagram illustrating a light emission spectrum of light emitted from two kinds of white light emitters when the light emission intensities of the two kinds of white light emitters are equalized in the third embodiment.

FIG. 33 is a diagram illustrating a light emission spectrum of light emitted from two kinds of white light emitters when the color temperature is set to 6500 K in the third embodiment.

FIG. 34 is a diagram illustrating a light emission spectrum of light emitted from two kinds of white light emitters when the color temperature is set to 9300 K in the third embodiment.

FIG. 35 is a diagram illustrating an arrangement of light sources in a first modified example of the third embodiment.

FIG. 36 is a diagram illustrating an arrangement of light sources in a second modified example of the third embodiment.

FIG. 37 is a diagram illustrating a configuration of the light source mounted on a LED substrate in a third modified example of the third embodiment.

FIG. 38 is a xy chromaticity diagram for describing switching of color temperature in the third modified example of the third embodiment.

FIG. 39 is a diagram for describing a backlight device in the related art.

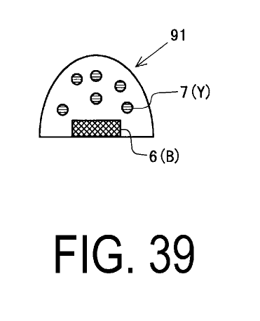

FIG. 40 is a diagram for describing a backlight device in the related art.

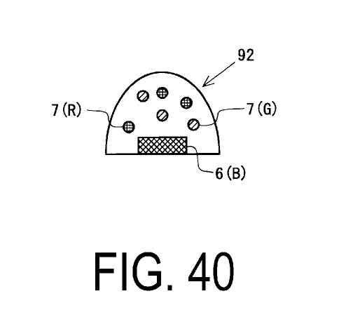

FIG. 41 is a diagram for describing a backlight device in the related art.

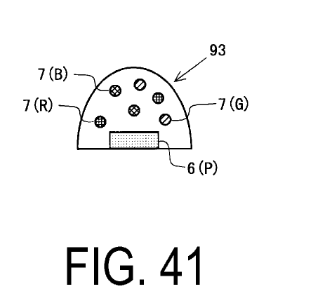

FIG. 42 is a diagram for describing a backlight device in the related art.

### DESCRIPTION OF EMBODIMENTS

Embodiments of the present invention will be described with reference to the accompanying drawings. Note, descriptions of the same points as those of the first embodiment are omitted as appropriate with respect to the second embodiment and the third embodiment. Further, in the present specification, a light emitter having a light emitting element (LED element or the like) and a wavelength conversion element (phosphor or the like) for converting the wavelength of light emitted from the light emitting element is referred to as “first type light emitter,” and a light emitter having only a light emitting element is referred to as “second type light emitter”.

### First Embodiment

### 1.1 Overall Configuration and Outline of Operations

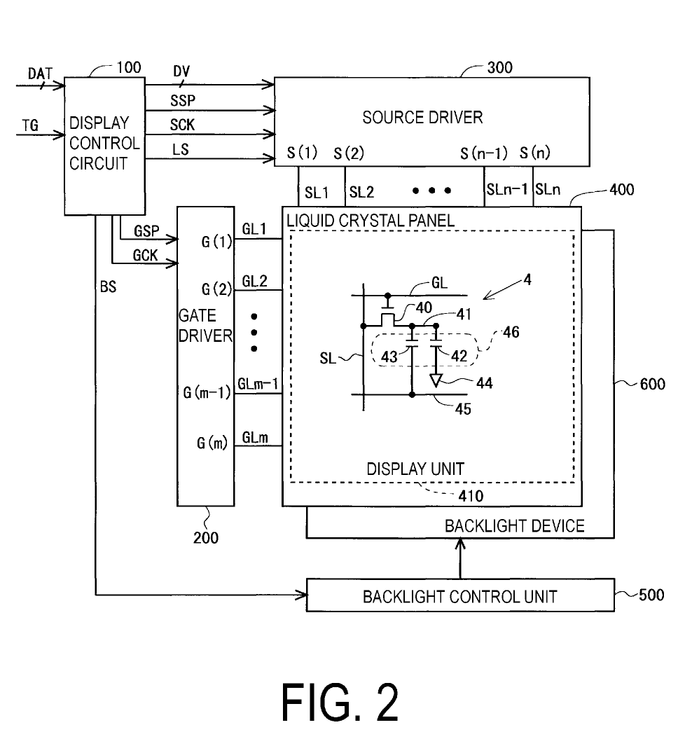

FIG. 2 is a block diagram illustrating the overall configuration of a liquid crystal display device having a backlight device 600 according to a first embodiment of the present invention. The liquid crystal display device is composed of a display control circuit 100, a gate driver (scanning signal line driving circuit) 200, a source driver (video signal line driving circuit) 300, a liquid crystal panel 400, a backlight control unit 500, and a backlight device 600. The liquid crystal panel 400 includes a display unit 410 for displaying an image. Note that the gate driver 200 or the source driver 300 or both may be provided in the liquid crystal panel 400.

Referring to FIG. 2, a plurality of (n) source bus lines (video signal lines) SL1 to SLn and a plurality (m) of gate bus lines (scanning signal lines) GL1 to GLm are provided in the display unit 410. Pixel forming units 4 for forming pixels are provided corresponding to intersections of source bus lines SL1 to SLn and gate bus lines GL1 to GLm. That is, the display unit 410 includes a plurality (n×m) of pixel forming units 4. The plurality of pixel forming units 4 are arranged in a matrix and form a pixel matrix. Each pixel forming unit 4 includes: a TFT (thin film transistor) 40, which is a switching element having a gate terminal connected to a gate bus line GL passing through a corresponding intersection and a source terminal connected to a source bus line SL passing through the intersection;

a pixel electrode 41 connected to the drain terminal of the TFT 40;

a common electrode 44 and an auxiliary capacitance electrode 45 commonly provided in the plurality of pixel forming units 4;

a liquid crystal capacitor 42 formed by the pixel electrode 41 and the common electrode 44; and

an auxiliary capacitor 43 formed by the pixel electrode 41 and the auxiliary capacitance electrode 45.

The pixel capacitor 46 is composed of the liquid crystal capacitor 42 and the auxiliary capacitor 43. In the display unit 410 in FIG. 2, only the components corresponding to one pixel forming unit 4 are illustrated.

An oxide TFT (a thin film transistor using an oxide semiconductor for a channel layer) can be adopted as the TFT 40 in the display unit 410, for example. More specifically, a TFT (hereinafter also referred to as “In—Ga—Zn—O-TFT”) can be adopted as the TFT 40 with In—Ga—Zn—O (indium gallium zinc oxide), which is an oxide semiconductor containing the main components indium (In), gallium (Ga), zinc (Zn), and oxygen (O) that forms the channel layer. By adopting this In—Ga—Zn—O-TFT, in addition to the effect of achieving high definition and low power consumption, the writing speed can be increased beyond conventional levels. Alternatively, a transistor including an oxide semiconductor other than In—Ga—Zn—O (indium gallium zinc oxide) as a channel layer can be adopted. For example, the same effect can be obtained also when a transistor using an oxide semiconductor for a channel layer is adopted containing at least one of indium, gallium, zinc, copper (Cu), silicon (Si), tin (Sn), aluminum (Al), calcium (Ca), germanium (Ge), and lead (Pb). Note, the present invention does not exclude the use of TFTs other than oxide TFTs.

Next, the operation of the components illustrated in FIG. 2 will be described. The display control circuit 100 receives an image signal DAT sent from the outside and a timing signal group TG such as a horizontal synchronization signal and a vertical synchronization signal, and outputs:

a digital video signal DV, a gate start pulse signal GSP and a gate clock signal GCK for controlling the operation of the gate driver 200;

a source start pulse signal SSP, a source clock signal SCK, and a latch strobe signal LS for controlling the operation of the source driver 300; and

a backlight control signal BS for controlling the operation of the backlight control unit 500.

Based on the gate start pulse signal GSP and the gate clock signal GCK sent from the display control circuit 100, the gate driver 200 outputs the active scan signals G(1) to G(m) to the respective gate bus lines GL1 to GLm, which is repeated with one vertical scanning period as one cycle.

The source driver 300 receives the digital video signal DV, the source start pulse signal SSP, the source clock signal SCK, and the latch strobe signal LS sent from the display control circuit 100 and supplies the driving video signal S(1) to S(n) to the source bus lines SL1 to SLn. At this time, in the source driver 300, at the timing when the pulse of the source clock signal SCK is generated, the digital video signal DV indicating the voltage to be applied to each of the source bus lines SL1 to SLn is sequentially held. Then, at the timing when the pulse of the latch strobe signal LS is generated, the held digital video signal DV is converted into an analog voltage. The converted analog voltage is simultaneously applied to all the source bus lines SL1 to SLn as the driving video signals S(1) to S(n).

The backlight control unit 500 controls the luminance (light emission intensity) of the light source in the backlight device 600 based on the backlight control signal BS sent from the display control circuit 100.

As described above, the scanning signals G(1) to G(m) are applied to the respective gate bus lines GL1 to GLm, and the driving video signal driving video signals S(1) to S(n) are applied to the respective source bus lines SL1 to SLn, and the luminance of the light source in the backlight device 600 is controlled, whereby an image corresponding to the image signal DAT sent from the outside is displayed on the display unit 410.

### 1.2 Configuration of Backlight Device

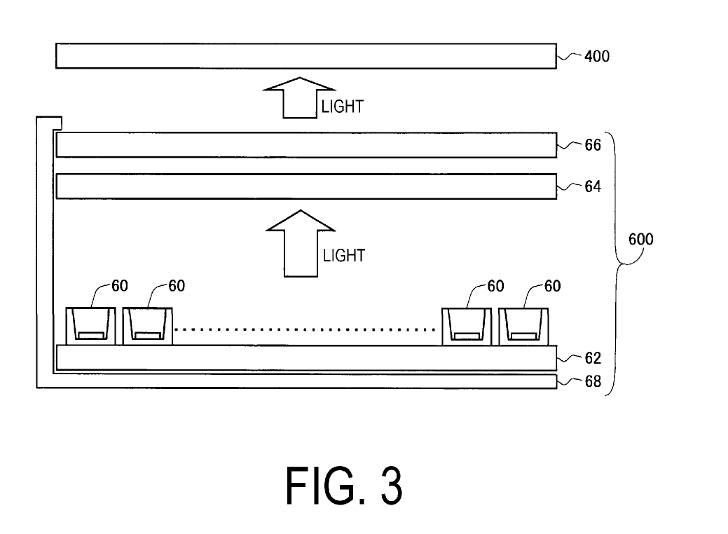

FIG. 3 is a diagram illustrating an example of a schematic configuration of the backlight device 600 according to the present embodiment. FIG. 3 is a side view of the liquid crystal panel 400 and the backlight device 600. The backlight device 600 is provided on the back side of the liquid crystal panel 400. That is, the backlight device 600 in this embodiment is a directly below type. The backlight device 600 includes an LED substrate 62 on which a plurality of light emitters 60 as light sources are mounted, a diffusion plate 64 for diffusing and homogenizing the light emitted from the light emitters 60, an optical sheet 66 for increasing the efficiency of the light irradiated toward the liquid crystal panel 400, and a chassis 68 for supporting the LED substrate 62.

### 1.3 Configuration of Light Source

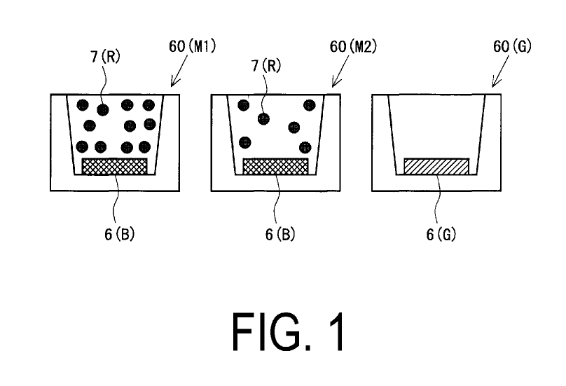

FIG. 1 is a diagram illustrating a configuration of a light source mounted on a LED substrate 62. As illustrated in FIG. 1, in the present embodiment, the light source includes a first magenta light emitter 60 (M1) having a structure in which the blue LED element 6 (B) is covered with a relatively large amount of the red phosphor 7 (R), a second magenta light emitter 60 (M2) having a structure in which the blue LED element 6 (B) is covered with a relatively small amount of red phosphor 7 (R), and a green light emitter 60 (G) composed of a green LED element 6 (G). The first magenta light emitter 60 (M1) and the second magenta emitter 60 (M2) are first type emitters and the green emitter 60 (G) is a second type emitter. In this manner, in the present embodiment, the light source is composed of two kinds of first type light emitters and one kind of second type light emitters.

Blue light is emitted from the blue LED element 6 (B), and green light is emitted from the green LED element 6 (G). Red light is emitted from the red phosphor 7 (R). The red phosphor 7 (R) is excited by light emitted from the blue LED element 6 (B) to emit light. That is, the red phosphor 7 (R) functions as a wavelength conversion element that converts the wavelength of blue light into the wavelength of red light. As described above, the first magenta light emitter 60 (M1) contains a relatively large amount of the red phosphor 7 (R), and the second magenta emitter 60 (M2) contains a relatively small amount of the red phosphor 7 (R). As described above, the first magenta light emitter 60 (M1) emits reddish magenta light, the second magenta emitter 60 (M2) emits bluish magenta light, and the green light emitter 60 (G) emits green light. Reddish magenta light, bluish magenta light, and green light are synthesized, and white light is irradiated to the liquid crystal panel 400.

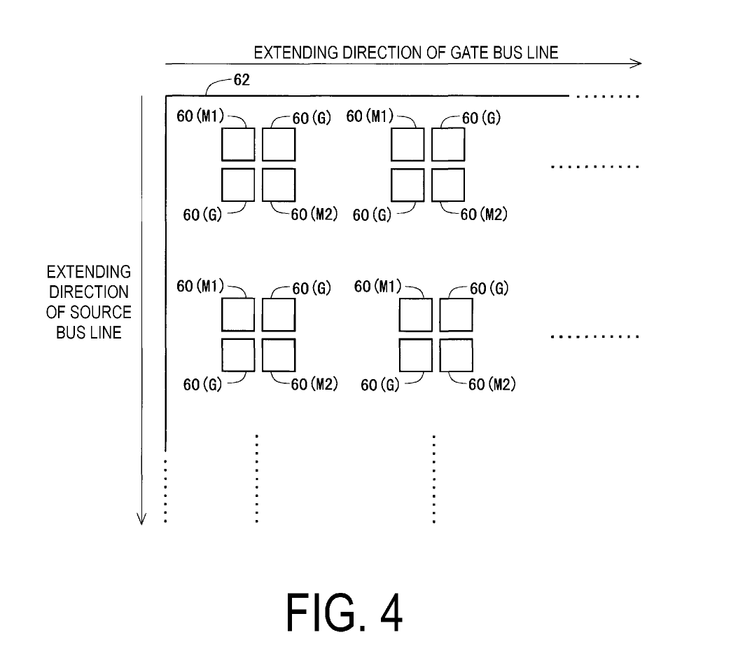

FIG. 4 is a diagram illustrating the arrangement of the light sources on the LED substrate 62. As illustrated in FIG. 4, in the present embodiment, one first magenta light emitter 60 (M1), one second magenta emitter 60 (M2), two green light emitters 60 (G) form one group. That is, four light emitters 60 are included in one group. Focusing on each group, the first magenta light emitter 60 (M1) is disposed in the upper left side, the second magenta light emitter 60 (M2) is disposed in the lower right side, and the green light emitters 60 (G) are disposed in the upper right side and lower left side. Such groups are disposed at regular intervals in the extending direction of the gate bus lines GL and are also disposed at regular intervals in the extending direction of the source bus lines SL.

The chromaticity of the first magenta light emitter 60 (M1), the second magenta emitter 60 (M2) and the green light emitter 60 (G) are different from each other. Depending on the color temperature to be displayed, deviations occur in their light emission intensities. From the foregoing, there is concern that color unevenness and luminance unevenness may occur depending on the arrangement of the light source. Therefore, the four light emitters 60 included in each group are arranged close to each other so as to suppress occurrence of color unevenness and luminance unevenness is preferable.

### 1.4 Regarding Control of Light Emission Intensity

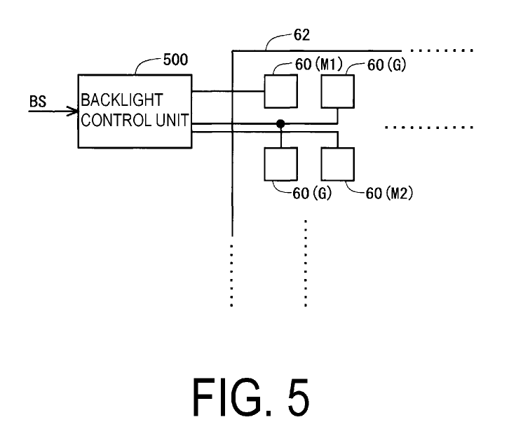

Next, the control of the light emission intensity of the light emitter 60 will be described. FIG. 5 is a diagram for describing a configuration for controlling the light emission intensity of the light emitter 60. Although only the light emitters 60 included in one group are illustrated in FIG. 5, the light emitters 60 included in all the groups are similarly controlled.

As illustrated in FIG. 5, the first magenta light emitter 60 (M1), the second magenta emitter 60 (M2), and the green light emitters 60 (G) are independently connected to the backlight controller 500. Since such a configuration is adopted, the light emission intensity of the light emitters 60 on the LED substrate 62 is adjusted for each kind. That is, the light emission intensity of the first magenta light emitter 60 (M1), the light emission intensity of the second magenta emitter 60 (M2), and the light emission intensity of the green emitter 60 are independently controlled by the backlight control unit 500. As a method of controlling the light emission intensity of the light emitters 60, for example, the method of adjusting the magnitude of a current applied to the LED element 6 in the light emitter 60 and PWM control of a constant current to the LED element 6 in the light emitter 60 can be adopted. The light emission intensity of each light emitter 60 is controlled based on the backlight control signal BS sent from the display control circuit 100.

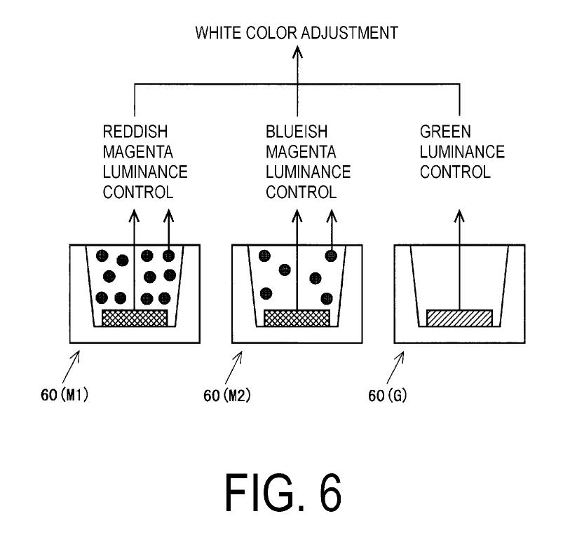

As described above, as illustrated in FIG. 6, by controlling the light emission intensity of the first magenta light emitter 60 (M1), the reddish magenta color luminance is controlled; by controlling the light emission intensity of the second magenta light emitter 60 (M2), the luminance of the bluish magenta color is controlled; and by controlling the light emission intensity of the green light emitter 60 (G), the green luminance is controlled. As a result, white adjustment (adjustment and change of color temperature) is performed.

### 1.5 Color Temperature Switching

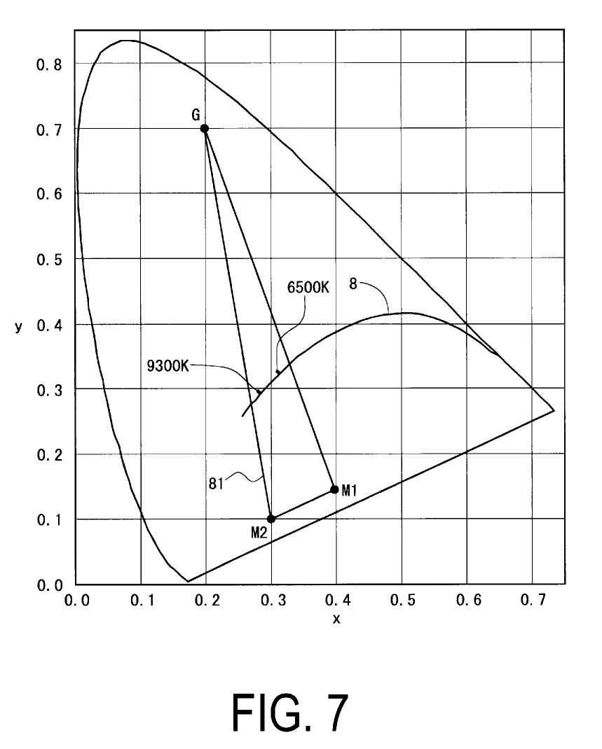

Next, how color temperature is switched in this embodiment will be described. In the following description, an example will be described in which the color temperature is switched between 6500 K and 9300 K. As described above, in the present embodiment, the light emission intensity of the first magenta light emitter 60 (M1), the light emission intensity of the second magenta emitter 60 (M2), and the light emission intensity of the green light emitters 60 (G) are independently controlled by the backlight control unit 500. That is, the luminance of the three colors of reddish magenta, bluish magenta, and green are independently controlled. Therefore, on the xy chromaticity diagram, chromaticity coordinates within the range of a triangle 81 connecting the chromaticity coordinates (green chromaticity coordinates) G for the green light emitter 60, chromaticity coordinates (chromaticity coordinates of reddish magenta color) M1 for the first magenta light emitter 60 (M1), and chromaticity coordinates (bluish magenta chromaticity coordinates) M2 for the second magenta light emitter 60 (M2) can be selected as a white point (see FIG. 7).

It is assumed that the light emitter 60 constituting the light source is selected so that chromaticity coordinates corresponding to the target color temperature are included within the range of the triangle 81. In the example illustrated in FIG. 7, the chromaticity coordinates for the green light emitter 60 (G) are (0.2, 0.7), the chromaticity coordinates for the first magenta light emitter 60 (M1) is (0.4, 0.15), and the chromaticity coordinates for the second magenta light emitter 60 (M2) are (0.3, 0.1).

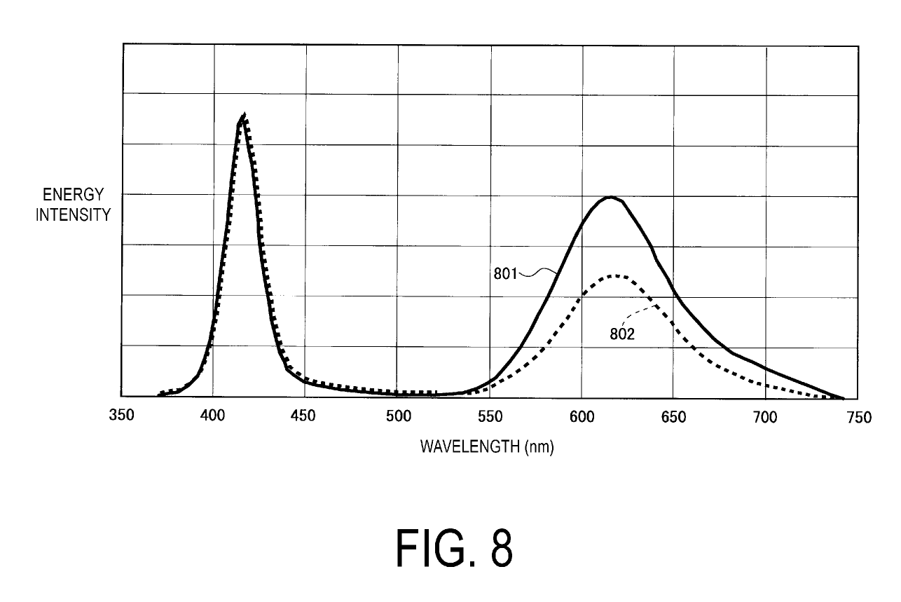

When the light emission intensity of the first magenta light emitter 60 (M1) and the light emission intensity of the second magenta light emitter 60 (M2) are equalized, the light emission spectrum of the light emitted from the first magenta light emitter 60 (M1) is represented by a curve indicated by reference numeral 801 in FIG. 8, for example, and the light emission spectrum of the light emitted from the second magenta light emitter 60 (M2) is represented by a curve indicated by reference numeral 802 in FIG. 8, for example.

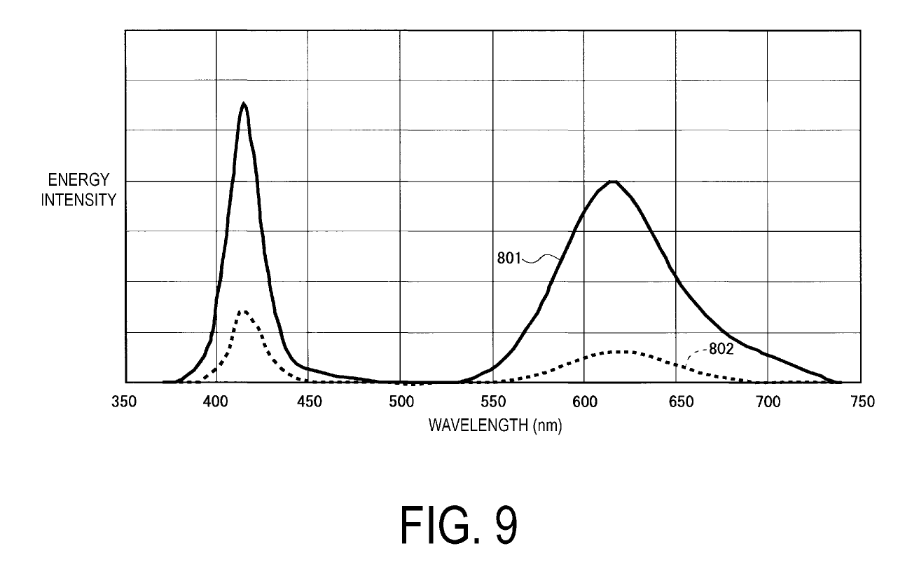

Under the above assumption, when setting the color temperature to 6500 K, the light emission intensity of the first magenta light emitter 60 (M1) is relatively strengthened and the light emission intensity of the second magenta light emitter 60 (M2) is relatively weakened. As a result, the light emission spectrum 801 of the light emitted from the first magenta light emitter 60 (M1) and the light emission spectrum 802 of the light emitted from the second magenta light emitter 60 (M2) are as illustrated in FIG. 9, for example. As a result, the chromaticity coordinates of the combined light of the light emitted from the first magenta light emitter 60 (M1) and the light emitted from the second magenta emitter 60 (M2) becomes coordinates close to the chromaticity coordinates M1 of the light emitted from the first magenta light emitter 60 (M1). Further, the light emission intensity of the green light emitter 60 (G) is adjusted so that the white point is located on the blackbody locus 8 on the xy chromaticity diagram. As described above, the color temperature is set to 6500 K.

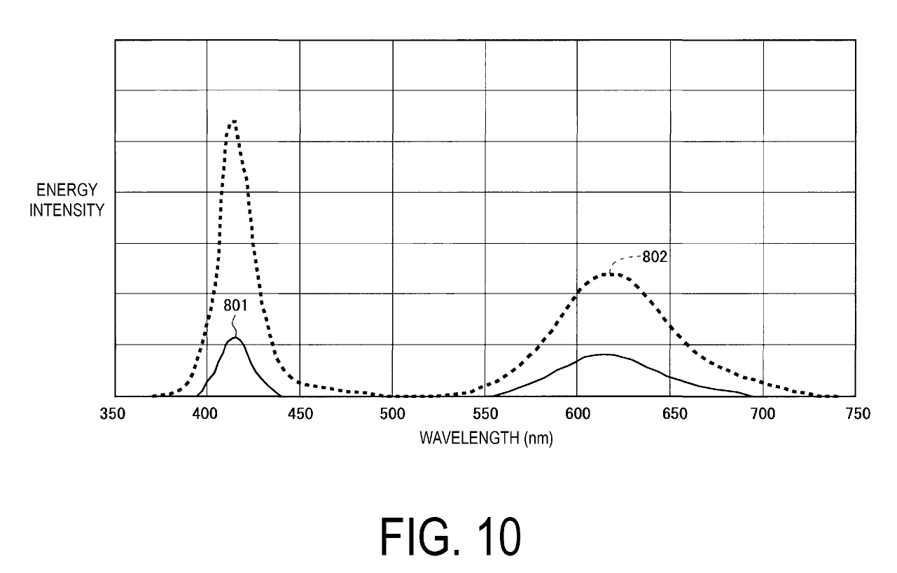

When setting the color temperature to 9300 K, the light emission intensity of the first magenta light emitter 60 (M1) is relatively weakened and the light emission intensity of the second magenta emitter 60 (M2) is relatively strengthened. As a result, the light emission spectrum 801 of the light emitted from the first magenta light emitter 60 (M1) and the light emission spectrum 802 of the light emitted from the second magenta light emitter 60 (M2) are as illustrated in FIG. 10, for example. As a result, the chromaticity coordinates of the combined light of the light emitted from the first magenta light emitter 60 (M1) and the light emitted from the second magenta light emitter 60 (M2) becomes coordinates close to the chromaticity coordinates M2 of the light emitted from the second magenta light emitter 60 (M2).

Further, the light emission intensity of the green light emitter 60 (G) is adjusted so that the white point is located on the blackbody locus 8 on the xy chromaticity diagram. As described above, the color temperature is set to 9300 K.

### 1.6 Effects

In the present embodiment, the light source constituting the backlight device 600 is composed of:

a green light emitter 60 (G) having a green LED element 6 (G);

a first magenta light emitter 60 (M1) having a structure in which the blue LED element 6 (B) is covered with a relatively large amount of the red phosphor 7 (R); and

a second magenta light emitter 60 (M2) having a structure in which the blue LED element 6 (B) is covered with a relatively small amount of red phosphor 7 (R) (See FIG. 1). In this manner, the light source is composed of three types of light emitters 60. In addition, the three types of light emitters 60 are configured so that the light emission intensities are independently controlled. As a result, since the luminance of light of three colors can be independently controlled, it is possible to adjust and change the color temperature.

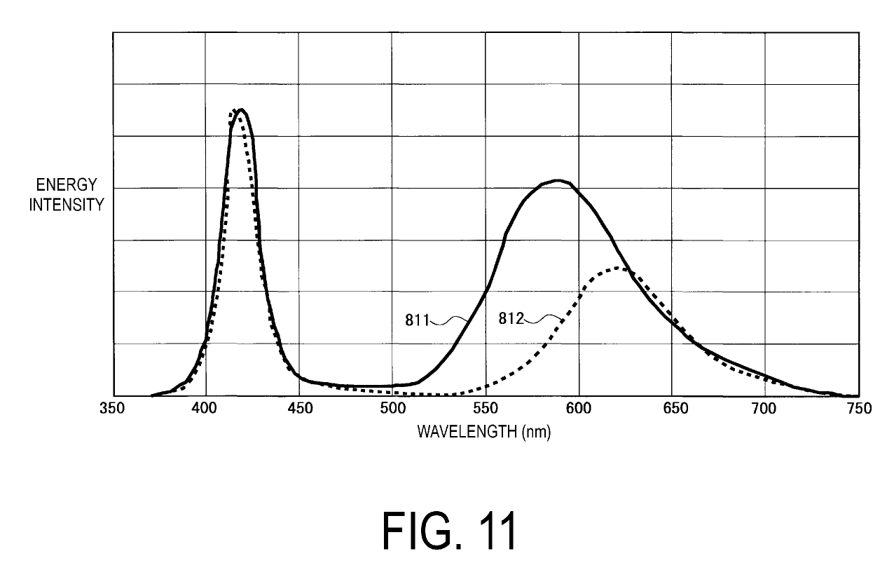

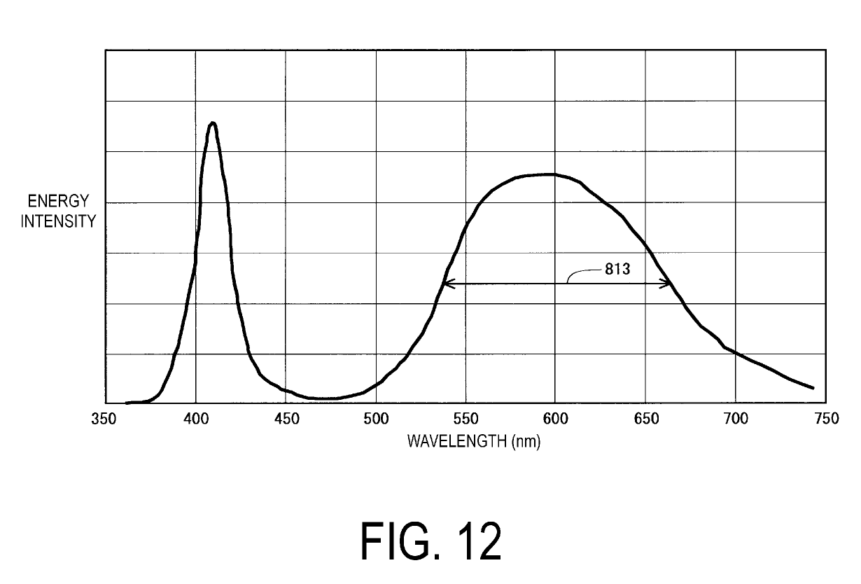

Two types of light emitters (the first magenta light emitter 60 (M1) and the second magenta light emitter (M2)) out of the above three types of light emitters 60 include the same type of LED element (LED chip) as the light emitting element and the same type of phosphor as the wavelength conversion element. In this regard, if two kinds of light emitters (two kinds of magenta light emitters) are configured by using two kinds of red phosphors having mutually different light emission wavelengths, that is, assuming two kinds of magenta light emitters are formed by a magenta light emitter having a light emission spectrum represented by a curve indicated by reference numeral 811 in FIG. 11 and a magenta light emitter having a light emission spectrum represented by a curve indicated by reference numeral 812 in FIG. 11, since the light emission spectrum of red differs between the two kinds of magenta light emitters, the curve representing the light emission spectrum of the combined light as illustrated in FIG. 12. As understood from FIG. 12, the half-value width (the portion indicated by the arrow in reference numeral 813 in FIG. 12) of the light emission spectrum is larger than the original one. Therefore, when two kinds of light emitters (two kinds of magenta light emitters) are configured by using two kinds of red phosphors having mutually different light emission wavelengths, the color purity is lowered. In this regard, in this embodiment, the first magenta color light emitter 60 (M1) and the second magenta color light emitter 60 (M2) contain the same kind of LED elements and contain the same kind of phosphor. Therefore, regardless of how the light emission intensities of the first magenta light emitter 60 (M1) and the second magenta emitter 60 (M2) are controlled, the dominant wavelength of the combined light does not change and the half-value width of the combined light is maintained at a relatively narrow width. Therefore, the color purity does not decrease.

Further, in the present embodiment, the light source does not include a red LED element. As described above, since the red LED element has an output largely changing depending on the temperature, reliability is improved by adopting a configuration that does not use the red LED element.

As described above, according to the present embodiment, it is possible to realize a highly reliable backlight device capable of adjusting and changing the color temperature without lowering the color purity.

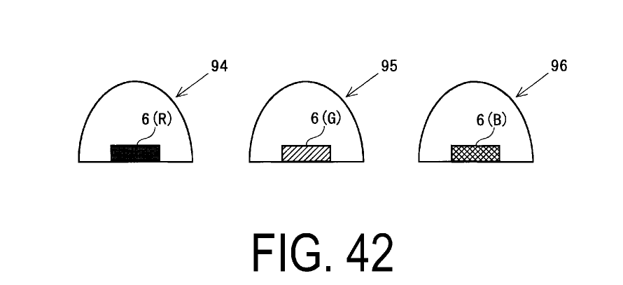

Further, according to the present embodiment, as described above, since the configuration without using the red LED element is adopted, the backlight device with low power consumption can be realized at low costs. This will be described below. Red LED elements are less efficient than blue LED elements. Therefore, power consumption is reduced by adopting a configuration that does not use a red LED element. In addition, white LEDs are often realized by using blue LED elements. For this reason, improvements have been made with respect to the blue LED element and mass production is being carried out, thereby lowering the unit price of the chip. Further, in the present embodiment, unlike the configuration illustrated in FIG. 42 and the configuration disclosed in JP 2008-205133 A, only two kinds of LED elements (LED chips) are used. Since the forward voltage and temperature characteristics are different for each kind of LED element, controlling the light source becomes easy by reducing the kind of LED element to be used. In particular, in the present embodiment, since the configuration that does not use a red LED element with high temperature dependency is adopted, controlling the light source becomes remarkably easier as compared with the configuration in the related art and costs are reduced.

### 1.7 Modified Example

Hereinafter, a modified example of the first embodiment will be described.

### 1.7.1 First Modified Example (Countermeasures Against Luminance Unevenness)

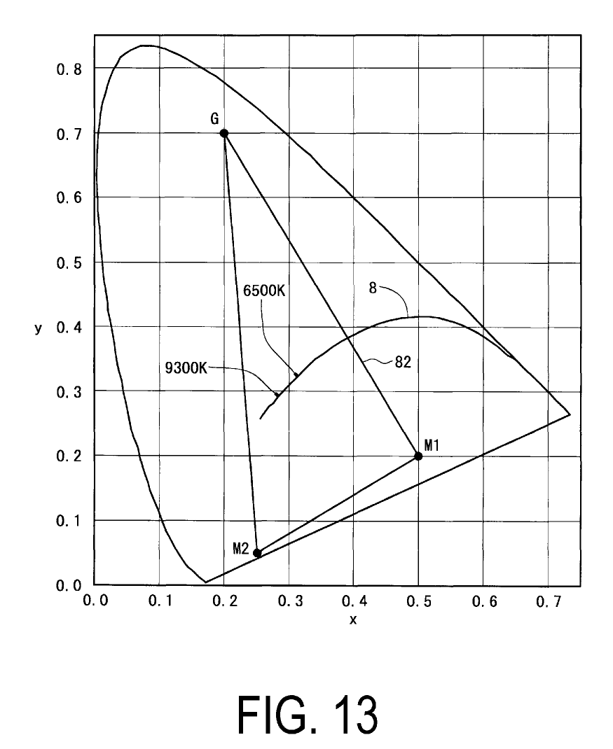

In the first embodiment, when the color temperature is set to 6500 K, the second magenta light emitter 60 (M2) is in a state close to the turned off state, and when the color temperature is set to 9300 K, the first magenta light emitter 60 (M1) is brought into a state close to the turned off state. When the state of the light emitter 60 close to the turned off state occurs in this way, luminance unevenness tends to occur on the screen. In this modified example (first modified example), the amount of the red phosphor 7 (R) included in each of the first magenta light emitter 60 (M1) and the second magenta light emitter 60 (M2) is adjusted so that the distance between the chromaticity coordinates M1 for the first magenta light emitter 60 (M1) and the chromaticity coordinates M2 of the second magenta light emitter 60 (M2) is longer than the distance in the first embodiment (see FIG. 13). In the example illustrated in FIG. 13, the chromaticity coordinates for the green light emitter 60 (G) are (0.2, 0.7), the chromaticity coordinates for the first magenta light emitter 60 (M1) are (0.5, 0.2), and the chromaticity coordinates for the second magenta light emitter 60 (M2) are (0.25, 0.05).

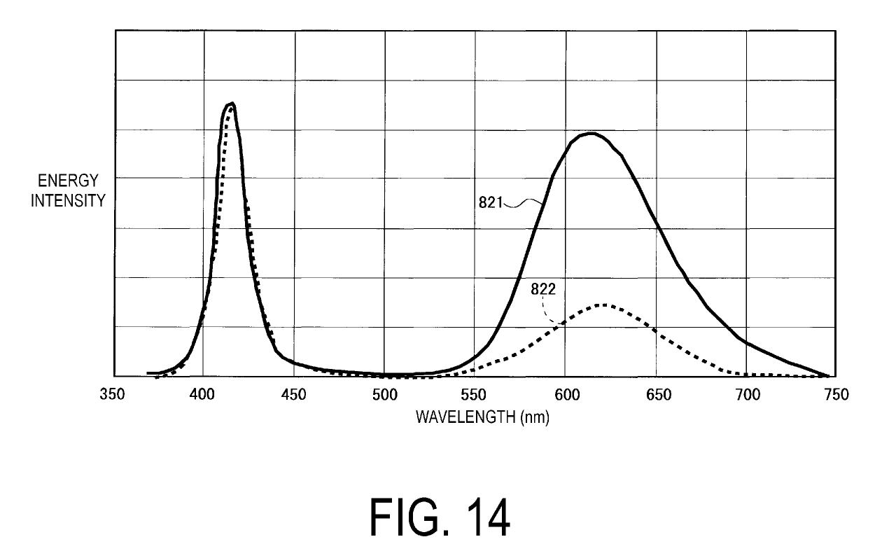

In this modified example, when the light emission intensity of the first magenta light emitter 60 (M1) and the light emission intensity of the second magenta light emitter 60 (M2) are equalized, the light emission spectrum of the light emitted from the first magenta light emitter 60 (M1) is represented by a curve indicated by reference numeral 821 in FIG. 14, for example, and the light emission spectrum of the light emitted from the second magenta light emitter 60 (M2) is represented by a curve indicated by reference numeral 822 in FIG. 14, for example.

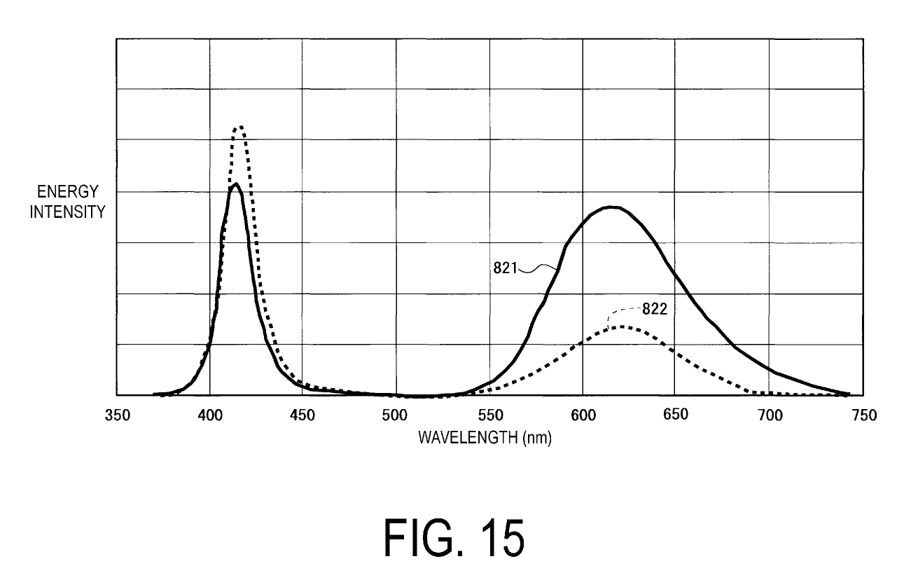

When setting the color temperature to 6500 K, the light emission intensity of the first magenta light emitter 60 (M1) and the light emission intensity of the second magenta light emitter 60 (M2) are controlled so that the light emission spectrum 821 of the light emitted from the first magenta color light emitter 60 (M1) and the emission spectrum 822 of the light emitted from the second magenta light emitter 60 (M2) are as illustrated in FIG. 15.

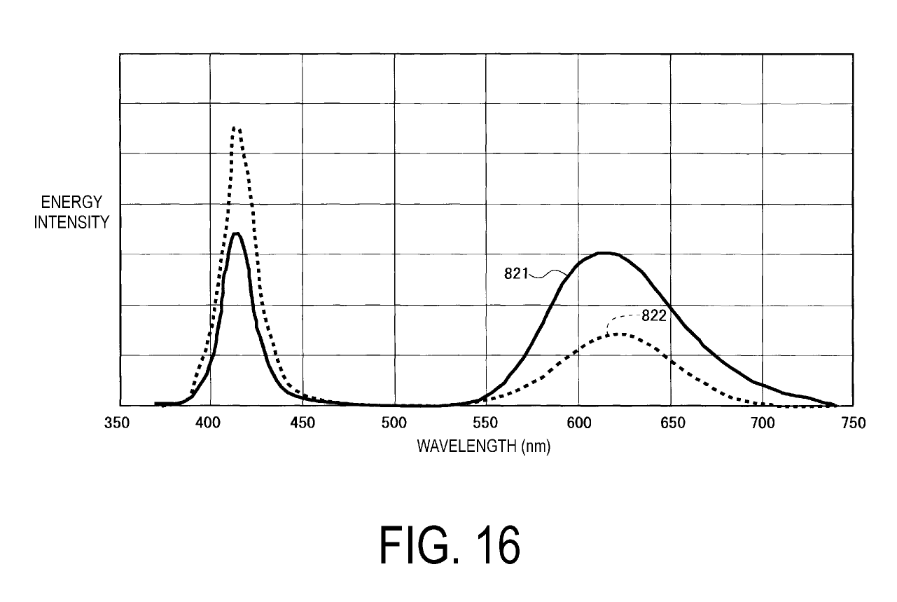

When setting the color temperature to 9300 K, the light emission intensity of the first magenta light emitter 60 (M1) and the light emission intensity of the second magenta light emitter 60 (M2) are controlled so that the light emission spectrum 821 of the light emitted from the first magenta light emitter 60 (M1) and the emission spectrum 822 of the light emitted from the second magenta light emitter 60 (M2) are as illustrated in FIG. 16.

As described above, in this modified example, even when the color temperature is set to either 6500 K or 9300 K, the first magenta light emitter 60 (M1) and the second magenta light emitter 60 (M2) are not in a state close to the turned off state. Therefore, occurrence of unevenness in luminance is suppressed. Further, on the xy chromaticity diagram, the range (see FIG. 13) of the triangle 82 connecting the chromaticity coordinates G for the green light emitter 60 (G), the chromaticity coordinates M1 for the first magenta light emitter 60 (M1) and the chromaticity coordinates M2 for the second magenta emitter 60 (M2) is wider than that of the first embodiment. Therefore, the range of displayable color temperature is widened.

The chromaticity coordinates of the light emitted from the first magenta light emitter 60 (M1) and the second magenta light emitter 60 (M2) varies according to the amount of the red phosphor 7 (R) included in each light emitter 60. Therefore, the range of the triangle connecting the chromaticity coordinates G for the green light emitter 60 (G), the chromaticity coordinates M1 for the first magenta light emitter 60 (M1) and the chromaticity coordinates for the second magenta light emitter 60 (M2) varies depending on the amount of red phosphor 7 (R) contained in each of the first magenta light emitter 60 (M1) and the second magenta light emitter 60 (M2). For example, the amount of the red phosphor 7 (R) included in the two kinds of the first type light emitters (the first magenta light emitter 60 (M1) and the second magenta light emitter 60 (M2)) is adjusted so that the chromaticity coordinates on the blackbody locus 8 corresponding to the color temperature in the range of 4000 K to 14000 K is included within the range of the triangle connecting the chromaticity coordinates of the light emitted from each of the three kinds of light emitters 60 described above. By performing such adjustment, the displayable color temperature range is 4000 K to 14000 K.

### 1.7.2 Arrangement of Light Sources

In the first embodiment, the light source on the LED substrate 62 is arranged as illustrated in FIG. 4. However, the present invention is not limited thereto. Various examples of arrangement of light sources on the LED substrate 62 will be described below. In each of the following modified examples, the light emission intensity of the first magenta light emitter 60 (M1), the light emission intensity of the second magenta light emitter 60 (M2), and the light emission intensity of the green light emitter 60 (G) are independently controlled by the backlight control unit 500.

### 1.7.2.1 Second Modified Example

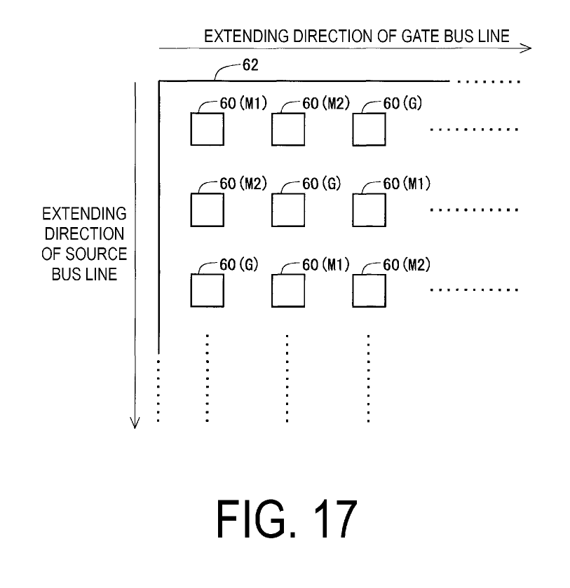

FIG. 17 is a diagram illustrating the arrangement of the light sources in the second modified example of the first embodiment. In the first row, the light emitters 60 are arranged at regular intervals in the order of “the first magenta light emitter 60 (M1), the second magenta light emitter 60 (M2), and the green light emitter 60 (G).” In the second row, the light emitters 60 are arranged at regular intervals in the order of “the second magenta light emitter 60 (M2), the green light emitter 60 (G), and the first magenta light emitter 60 (M1). In the third row, the light emitters 60 are arranged at regular intervals in the order of “the green light emitter 60 (G), the first magenta light emitter 60 (M1), and the second magenta light emitter 60 (M2).” The above configuration is repeated in the extending direction of the gate bus line GL and the extending direction of the source bus line SL.

However, according to the configuration illustrated in FIG. 17, depending on the color temperature to be displayed, the light emission intensities of the three kinds of light emitters 60 constituting the light source are biased. Therefore, in order to suppress the occurrence of color unevenness and luminance unevenness due to deviation of light emission intensity, arranging the light sources as in the first embodiment (see FIG. 4) is preferable.

### 1.7.2.2 Third Modified Example

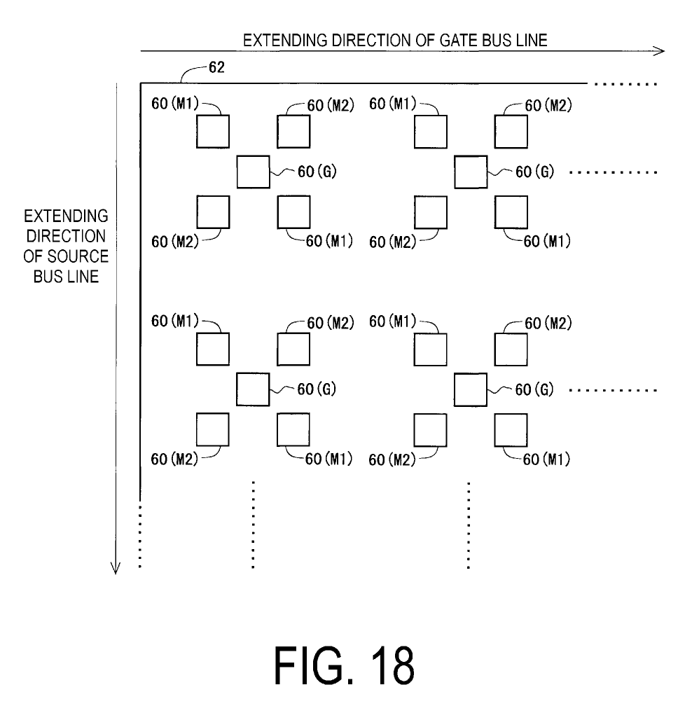

FIG. 18 is a diagram illustrating the arrangement of the light sources in the third modified example of the first embodiment. In this modified example, a coherent group is formed by two first magenta light emitter 60 (M1), two second magenta light emitters 60 (M2), and one green light emitter 60 (G). That is, five light emitters 60 are included in one group. Focusing on each group, the first magenta light emitter 60 (M1) is disposed at the upper left side and lower right side of the green light emitter 60 (G) in a plan view and the second magenta light emitter 60 (M2) is disposed at the upper right side and lower left side of the green light emitter 60 (G) in a plan view with the green light emitter 60 (G) at the center. Such groups are disposed at regular intervals in the extending direction the gate bus lines GL and are also disposed at regular intervals in the extending direction of the source bus lines SL. Further, the five light emitters 60 included in each group are arranged in close proximity to each other. Therefore, also in this modified example, occurrence of color unevenness and luminance unevenness is suppressed.

### 1.7.2.3 Fourth Modified Example

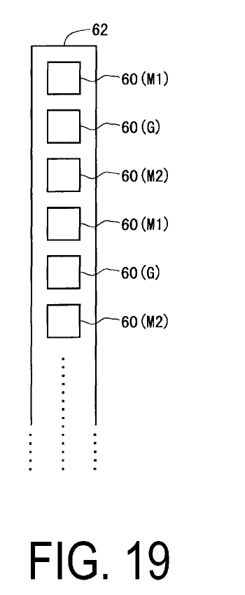

FIG. 19 is a diagram illustrating the arrangement of the light sources in the fourth modified example of the first embodiment. The configuration according to the present modified example is adopted when the backlight device is an edge light type. As illustrated in FIG. 19, in this modified example, a plurality of light emitters 60 are arranged in one line at regular intervals. Specifically, three kinds of light emitters 60 are arranged in one line and repeated in the order of “first magenta light emitter 60 (M1), green light emitter 60 (G), and second magenta light emitter 60 (M2).” Note that the order of the three types of light emitters 60 is not limited to the order of “the first magenta light emitter 60 (M1), the green light emitter 60 (G), and the second magenta light emitter 60 (M2).”

### 1.7.3 Configuration of Light Source

In the first embodiment, as illustrated in FIG. 1, the light source mounted on the LED substrate 62 is composed of a first magenta light emitter 60 (M1) having a structure in which a blue LED element 6 (B) is covered with relatively large amount of the red phosphor 7 (R), a second magenta light emitter 60 (M2) having a structure in which the blue LED element 6 (B) is covered with a relatively small amount of the red phosphor 7 (R), and a green light emitter 60 (G) having the green LED element 6 (G). However, the present invention is not limited thereto. A modified example of the configuration of the light source mounted on the LED substrate 62 will be described below.

### 1.7.3.1 Fifth Modified Example

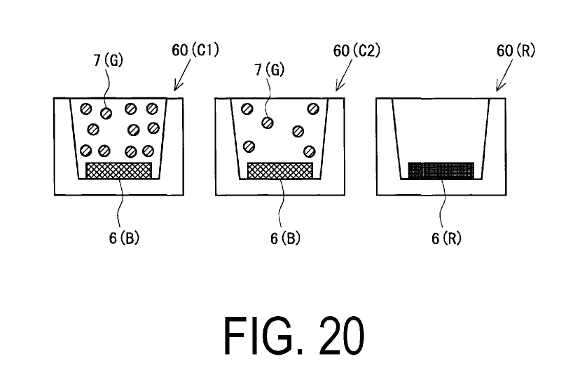

FIG. 20 is a diagram illustrating a configuration of the light source mounted on the LED substrate 62 in the fifth modified example of the first embodiment. As illustrated in FIG. 20, in this modified example, the light source is composed of a first cyan light emitter 60 (C1) having a structure in which the blue LED element 6 (B) is covered with a relatively large amount of the green phosphor 7 (G), a second cyan light emitter 60 (C2) having a structure in which the blue LED element 6 (B) is covered with a relatively small amount of the green phosphor 7 (G), and a red light emitter 60 (R) having the red LED element 6 (R). The first cyan light emitter 60 (C1) and the second cyan light emitter 60 (C2) are first type light emitters and the red light emitter 60 (R) is a second type light emitter.

The first cyan light emitter 60 (C1) emits a greenish cyan light, the second cyan light emitter 60 (C2) emits a bluish cyan light, and the red light emitter 60 (R) emits a red light. As a result of the greenish cyan light, the bluish cyan light, and the red light combining, the liquid crystal panel 400 is irradiated with white light.

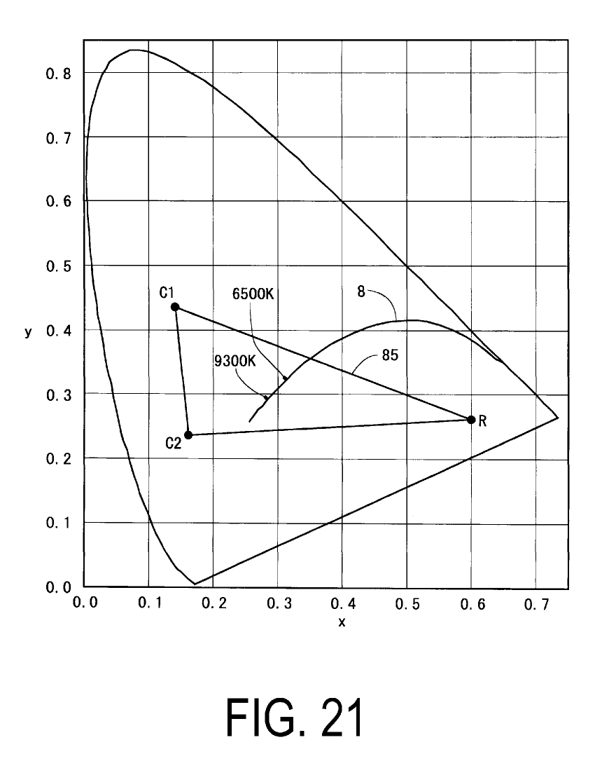

In the present modified example, the light emission intensity of the first cyan light emitter 60 (C1), the light emission intensity of the second cyan light emitter 60 (C2), and the light emission intensity of the red light emitter 60 (R) are independently controlled by the backlight control unit 500. That is, the luminance of the three colors of greenish cyan, bluish cyan and red is controlled independently. Therefore, on the xy chromaticity diagram, the chromaticity coordinates within the range of the triangle 85 connecting the chromaticity coordinates (red chromaticity coordinates) R for the red light emitter 60 (R), the chromaticity coordinates (chromaticity coordinates of greenish cyan) C1 for the first cyan light emitter 60 (C1), and the chromaticity coordinates (chromaticity coordinates of bluish cyan) C2 for the second cyan light emitter 60 (C2) can be selected as a white point (see FIG. 21). As described above, also in this modified example, it is possible to adjust and change the color temperature.

### 1.7.3.2 Sixth Modified Example

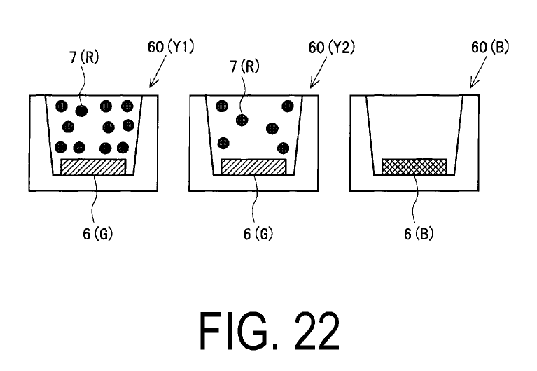

FIG. 22 is a diagram illustrating the configuration of the light source mounted on the LED substrate 62 in the sixth modified example of the first embodiment. As illustrated in FIG. 22, in this modified example, the light source includes a first yellow light emitter 60 (Y1) having a structure in which the green LED element 6 (G) is covered with a relatively large amount of the red phosphor 7 (R), a second yellow light emitter 60 (Y2) having a structure in which the green LED element 6 (G) is covered with a relatively small amount of the red phosphor 7 (R), and a blue light emitter 60 (B) having the blue LED element 6 (B). The first yellow light emitter 60 (Y1) and the second yellow light emitter 60 (Y2) are first type light emitters and the blue light emitters 60 (B) are second type light emitters.

The first yellow light emitter 60 (Y1) emits reddish yellow light, the second yellow light emitter 60 (Y2) emits greenish yellow light, and the blue light emitter 60 (B) emits blue light. Reddish yellow light, greenish yellow light, and blue light are combined, and white light is irradiated on the liquid crystal panel 400.

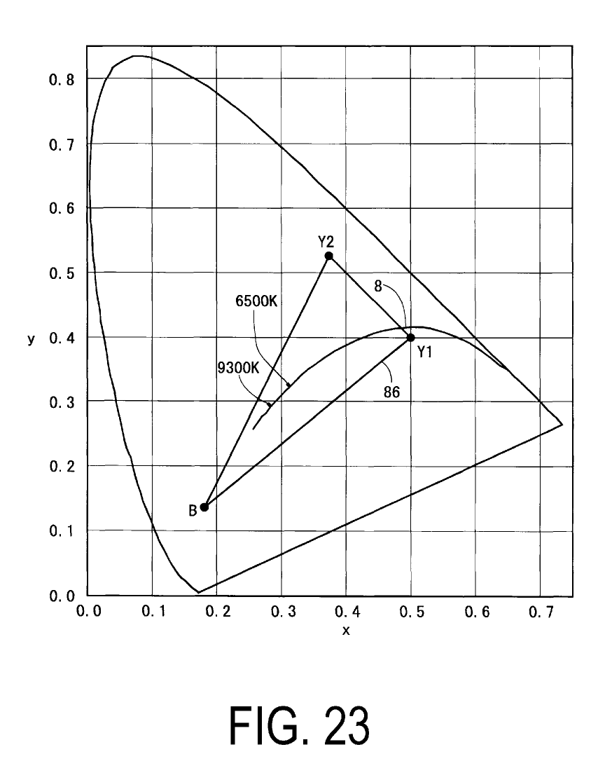

In this modified example, the light emission intensity of the first yellow light emitter 60 (Y1), the light emission intensity of the second yellow light emitter 60 (Y2), and the light emission intensity of the blue light emitter 60 (B) are independently controlled by the backlight control unit 500. That is, the luminance of the three colors of reddish yellow, greenish yellow, and blue are independently controlled. Accordingly, on the xy chromaticity diagram, the chromaticity coordinates within the range of the triangle 86 connecting the chromaticity coordinates (blue chromaticity coordinates) B for the blue light emitter 60 (B), chromaticity coordinates (reddish yellow chromaticity coordinates) Y1 for the first yellow light emitter 60 (Y1) and chromaticity coordinates (greenish yellow chromaticity coordinates) Y2 for the second yellow light emitter 60 (Y2) can be selected as a white point (see FIG. 23).

As described above, also in this modified example, it is possible to adjust and change the color temperature.

### Second Embodiment

### 2.1 Configuration, Etc.

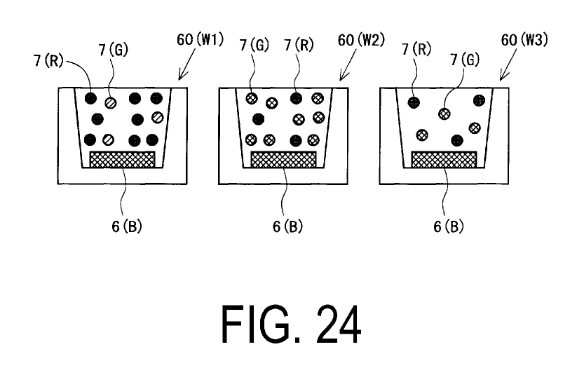

A second embodiment of the present invention will be described. The overall configuration (see FIG. 2) and the schematic configuration of the backlight device 600 (see FIG. 3) are similar to the first embodiment, so explanation is omitted. FIG. 24 is a diagram illustrating a configuration of the light source mounted on the LED substrate 62. As illustrated in FIG. 24, in the present embodiment, the light source is composed of:

a first white light emitter 60 (W1) having a structure in which the blue LED element 6 (B) is covered with a relatively large amount of the red phosphor 7 (R) and a relatively small amount of the green phosphor 7 (G);

a second white light emitter 60 (W2) having a structure in which the blue LED element 6 (B) is covered with a relatively small amount of the red phosphor 7 (R) and a relatively large amount of the green phosphor 7 (G); and

a third white light emitter 60 (W3) having a structure in which the blue LED element 6 (B) is covered with a relatively small amount of the red phosphor 7 (R) and a relatively small amount of the green phosphor 7 (G). The first white light emitter 60 (W1), the second white light emitter 60 (W2), and the third white light emitter 60 (W3) are first type light emitters. As described above, in the present embodiment, the light source is composed of three kinds of first type light emitters.

Blue light is emitted from the blue LED element 6 (B). Red light is emitted from the red phosphor 7 (R), and green light is emitted from the green phosphor 7 (G). The red phosphor 7 (R) and the green phosphor 7 (G) are excited by light emitted from the blue LED element 6 (B) to emit light. That is, the red phosphor 7 (R) functions as a wavelength conversion element that converts the wavelength of blue light into the wavelength of red light and the green phosphor 7 (G) functions as a wavelength conversion element that converts the wavelength of blue light into the wavelength of green light.

Since the first white light emitter 60 (W1) contains a relatively large amount of red phosphor 7 (R), the first white light emitter 60 (W1) emits reddish white light. Since the second white light emitter 60 (W2) contains a relatively large amount of the green phosphor 7 (G), the second white light emitter 60 (W2) emits greenish white light. Since the third white light emitter 60 (W3) contains a relatively small amount of red phosphor 7 (R) and a relatively small amount of green phosphor 7 (G), the third white light emitter 60 (W3) emits bluish white light. Reddish white light, greenish white light, and bluish white light are combined, and white light is irradiated on the liquid crystal panel 400.

The arrangement of the light sources on the LED substrate 62 can be similar to the first embodiment (see FIG. 4). However, in the present embodiment, the first magenta light emitter 60 (M1), the second magenta light emitter 60 (M2) and the green light emitter 60 (G) in the first embodiment are replaced with, for example, the white light emitter 60 (W1), the second white light emitter 60 (W2), and the third white light emitter 60 (W3), respectively.

Also in the present embodiment as in the first embodiment, the light emission intensity of the light emitter 60 on the LED substrate 62 is adjusted for each kind. That is, the light emission intensity of the first white light emitter 60 (W1), the light emission intensity of the second white light emitter 60 (W2), and the light emission intensity of the third white light emitter 60 (W3) are independently controlled by the backlight control unit 500.

As described above, the luminance of the reddish white is controlled by controlling the light emission intensity of the first white light emitter 60 (W1), the luminance of greenish white is controlled by controlling the light emission intensity of the second white light emitter 60 (W2), and the luminance of bluish white is controlled by controlling the light emission intensity of the third white light emitter 60 (W3). As a result, white adjustment (adjustment and change of color temperature) is performed.

### 2. 2. Color Temperature Switching

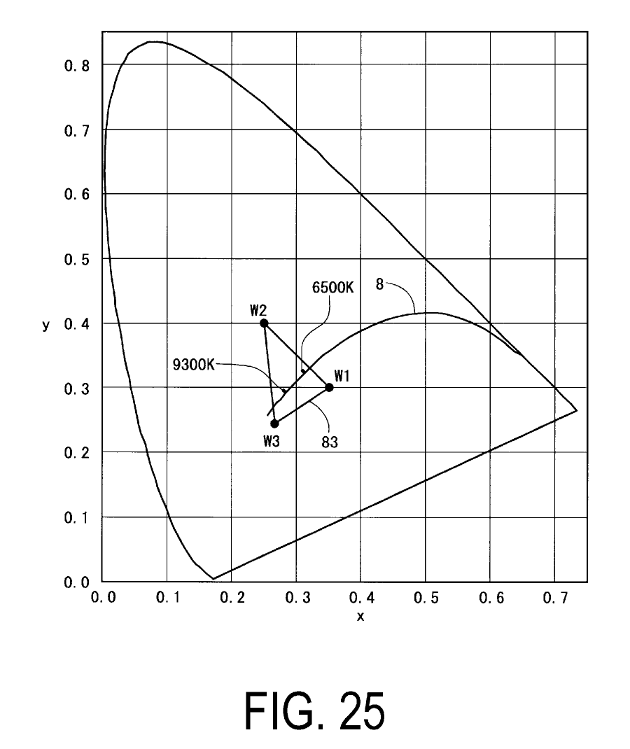

Next, how color temperature is switched in this embodiment will be described. Here too, an example in which the color temperature is switched between 6500 K and 9300 K will be described. In the present embodiment, the light emission intensity of the first white light emitter 60 (W1), the light emission intensity of the second white light emitter 60 (W2), and the light emission intensity of the third white light emitter 60 (W3) are independently controlled by the backlight control unit 500. That is, the luminance of the three colors of reddish white, greenish white, and bluish white are independently controlled. Accordingly, on the xy chromaticity diagram, chromaticity coordinates within the range of the triangle 83 connecting the chromaticity coordinates (chromaticity coordinates of reddish white) W1 for the first white light emitter 60 (W1), the chromaticity coordinates (chromaticity coordinate of greenish white) W2 for the second white light emitter 60 (W2) and the chromaticity coordinates (bluish white chromaticity coordinates) W3 for the third white light emitter 60 (W3) can be selected as a white point (see FIG. 25). It is assumed that the light emitter 60 constituting the light source is selected so that chromaticity coordinates corresponding to the target color temperature are included within the range of the triangle 83.

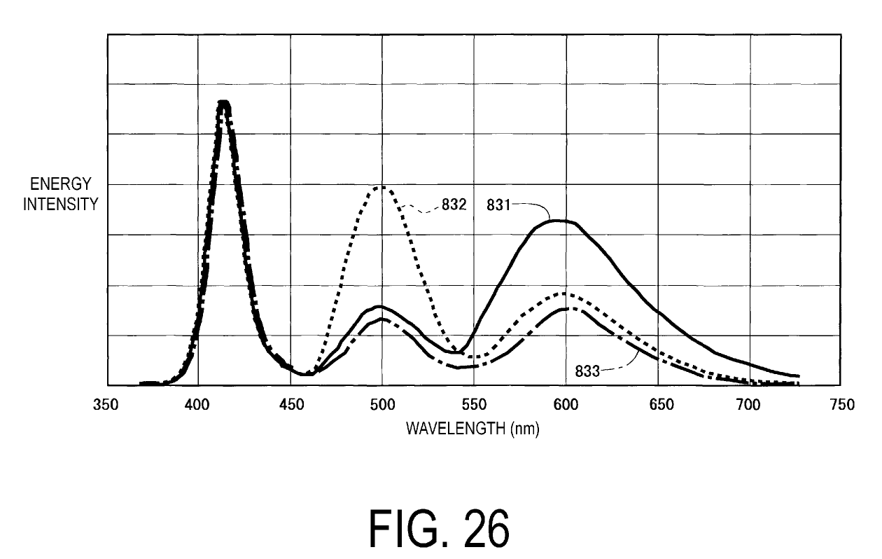

When the light emission intensities of the first white light emitter 60 (W1), the second white light emitter 60 (W2), and the third white light emitter 60 (W3) are equalized, the light emission spectrum of the light emitted from the first white light emitter 60 (W1) is represented by a curve indicated by reference numeral 831 in FIG. 26, for example, and the light emission spectrum of the light emitted from the second white light emitter 60 (W2) is represented by a curve indicated by reference numeral 832 in FIG. 26, for example, and the light emission spectrum of the light emitted from the third white light emitter 60 (W3) is represented by a curve indicated by reference numeral 833 in FIG. 26, for example.

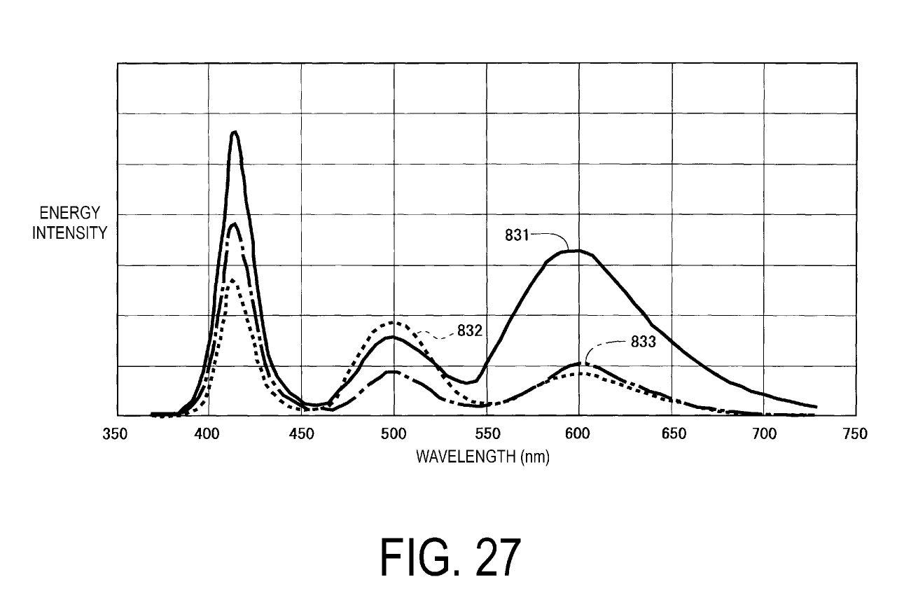

Under the above assumption, when setting the color temperature to 6500 K, the light emission intensity of the first white light emitter 60 (W1) is relatively increased, and the light emission intensity of the third white light emitter 60 (W3) relatively weakened. In addition, the light emission intensity of the second white light emitter 60 (W2) is adjusted so that the white point is located on the blackbody locus 8 on the xy chromaticity diagram. Thus, the light emission spectrum 831 of the light emitted from the first white light emitter 60 (W1), the light emission spectrum 832 of the light emitted from the second white light emitter 60 (W2), and the light emission spectrum 833 of the light emitted from the third white light emitter 60 (W3) is as illustrated in FIG. 27, for example. As described above, the color temperature is set to 6500 K.

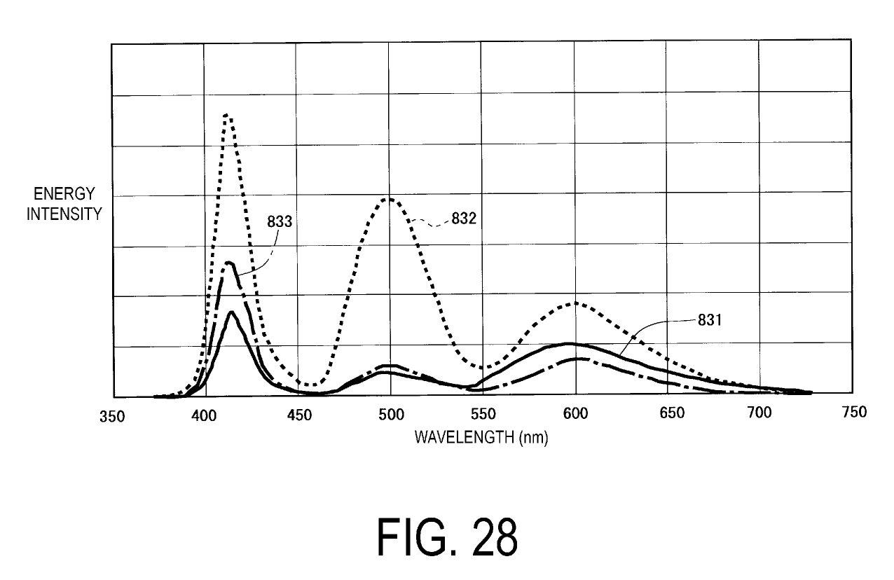

When setting the color temperature to 9300 K, the light emission intensity of the first white light emitter 60 (W1) is relatively weakened and the light emission intensity of the third white light emitter 60 (W3) is relatively strengthened. In addition, the light emission intensity of the second white light emitter 60 (W2) is adjusted so that the white point is located on the blackbody locus 8 on the xy chromaticity diagram. Thus, the light emission spectrum 831 of the light emitted from the first white light emitter 60 (W1), the light emission spectrum 832 of the light emitted from the second white light emitter 60 (W2), and the light emission spectrum 833 of the light emitted from the third white light emitter 60 (W3) is as illustrated in FIG. 28, for example. As described above, the color temperature is set to 9300 K.

### 2.3 Effects

In the present embodiment, the light source constituting the backlight device 600 is composed of:

a first white light emitter 60 (W1) having a structure in which the blue LED element 6 (B) is covered with a relatively large amount of the red phosphor 7 (R) and a relatively small amount of the green phosphor 7 (G);

a second white light emitter 60 (W2) having a structure in which the blue LED element 6 (B) is covered with a relatively small amount of the red phosphor 7 (R) and a relatively large amount of the green phosphor 7 (G); and

a third white light emitter 60 (W3) having a structure in which the blue LED element 6 (B) is covered with a relatively small amount of the red phosphor 7 (R) and a relatively small amount of the green phosphor 7 (G) (see FIG. 24).

In this manner, the light source is composed of three kinds of light emitters 60. In addition, the three kinds of light emitters 60 are configured so that the light emission intensities are independently controlled. As a result, since the luminance of light of three colors can be independently controlled, it is possible to adjust and change the color temperature. The three kinds of light emitters 60 include LED elements (LED chips) of the same kind as light emitting elements, and also contain phosphors of the same kind as wavelength conversion elements. Therefore, regardless of how the light emission intensities of the three kinds of light emitters 60 are controlled, the dominant wavelength of the combined light is not changed, and the half-value width of the combined light is maintained at a relatively narrow width. Therefore, even when the color temperature is adjusted or changed, the color purity does not decrease. Also, as in the first embodiment, the light source does not include a red LED element. As described above, according to the present embodiment, as in the first embodiment, realization of a highly reliable backlight device capable of adjusting and changing the color temperature without lowering the color purity is realized. Further, like the first embodiment, effects of lower power consumption and lower costs can be obtained.

### Third Embodiment

### 3.1 Configuration, Etc.

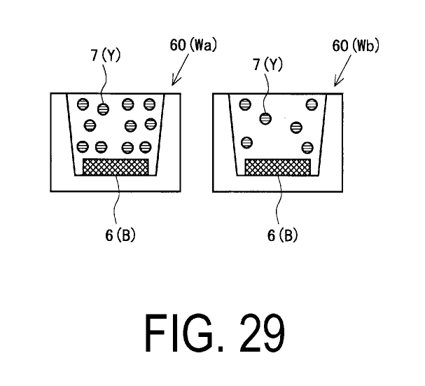

A third embodiment of the present invention will be described. The overall configuration (see FIG. 2) and the schematic configuration of the backlight device 600 (see FIG. 3) are similar to the first embodiment, so explanation is omitted. FIG. 29 is a diagram illustrating a configuration of a light source mounted on the LED substrate 62. As illustrated in FIG. 29, in the present embodiment, the light source is composed of a first white light emitter 60 (Wa) having a structure in which the blue LED element 6 (B) is covered with a relatively large amount of the yellow phosphor 7 (Y) and a second white light emitter 60 (Wb) having a structure in which the blue LED element 6 (B) is covered with a relatively small amount of the yellow phosphor 7 (Y).

The first white light emitter 60 (Wa) and the second white light emitter 60 (Wb) are first type light emitters. As described above, in the present embodiment, the light source is composed of two types of first type light emitters.

Blue light is emitted from the blue LED element 6 (B). Yellow light is emitted from the yellow phosphor 7 (Y). Note, the yellow phosphor 7 (Y) is excited by light emitted from the blue LED element 6 (B) and emits light. That is, the yellow phosphor 7 (Y) functions as a wavelength conversion element that converts the wavelength of blue light into the wavelength of yellow light. YAG (Yttirum Aluminum Garnet) phosphor can be used as the yellow phosphor 7 (Y), for example.

Since the first white light emitter 60 (Wa) contains a relatively large amount of the yellow phosphor 7 (Y), the first white light emitter 60 (Wa) emits yellowish white light. Since the second white light emitter 60 (Wb) contains a relatively small amount of the yellow phosphor 7 (Y), the second white light emitter 60 (Wb) emits bluish white light. As a result of combining yellowish white light and bluish white light, white light is irradiated on the liquid crystal panel 400.

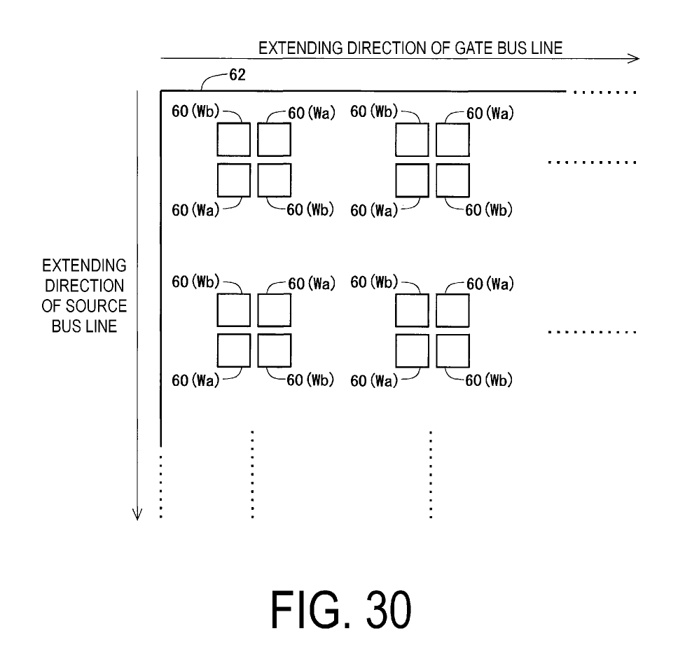

FIG. 30 is a diagram illustrating the arrangement of the light sources on the LED substrate 62. As illustrated in FIG. 30, in the present embodiment, one group is formed by two first white light emitters 60 (Wa) and two second white light emitters 60 (Wb). That is, four light emitters 60 are included in one group. Focusing on each group, in a plan view, the first white light emitter 60 (Wa) is disposed in the upper right side and lower left side and the second white light emitter 60 (Wb) is disposed in the upper left side and lower right side. Such groups are disposed at regular intervals in the extending direction the gate bus lines GL and are also disposed at regular intervals in the extending direction of the source bus lines SL. Similarly to the first embodiment, the four light emitters 60 included in each group are preferably arranged close to each other so as to suppress occurrence of color unevenness and luminance unevenness.

Moreover, similar to the first embodiment, in the present embodiment, the light emission intensity of the light emitter 60 on the LED substrate 62 is adjusted for each kind. That is, the light emission intensity of the first white light emitter 60 (Wa) and the light emission intensity of the second white light emitter 60 (Wb) are independently controlled by the backlight controller 500.

From the above, by controlling the light emission intensity of the first white light emitter 60 (Wa), the luminance of yellowish white is controlled, and by controlling the light emission intensity of the second white light emitter 60 (Wb), the luminance of bluish white is controlled. As a result, white adjustment (adjustment and change of color temperature) is performed.

### 3.2 Switching of Color Temperature

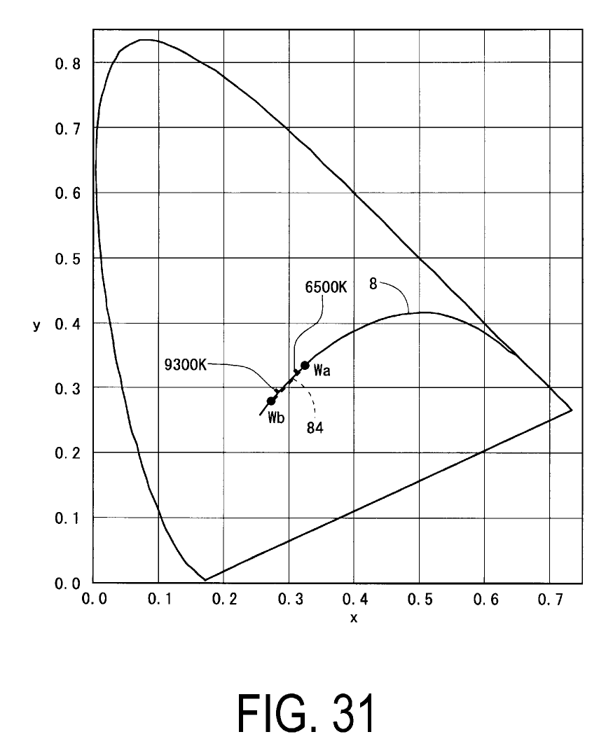

Next, how color temperature is switched in this embodiment will be described. Here too, an example in which the color temperature is switched between 6500 K and 9300 K will be described. In the present embodiment, the light emission intensity of the first white light emitter 60 (Wa) and the emission intensity of the second white light emitter 60 (Wb) are independently controlled by the backlight controller 500. That is, the luminance of the two colors of yellowish white and bluish white is independently controlled. Accordingly, on the xy chromaticity diagram, chromaticity coordinates on a line segment 84 connecting chromaticity coordinates (chromaticity coordinates of yellowish white) Wa for the first white light emitter 60 (Wa) and chromaticity coordinates (bluish white chromaticity coordinates) Wb for the second white light emitter 60 (Wb) are set as a white point (see FIG. 31). It is assumed that the light emitter 60 constituting the light source is selected so that the chromaticity coordinates corresponding to the target color temperature are located on the line segment 84.

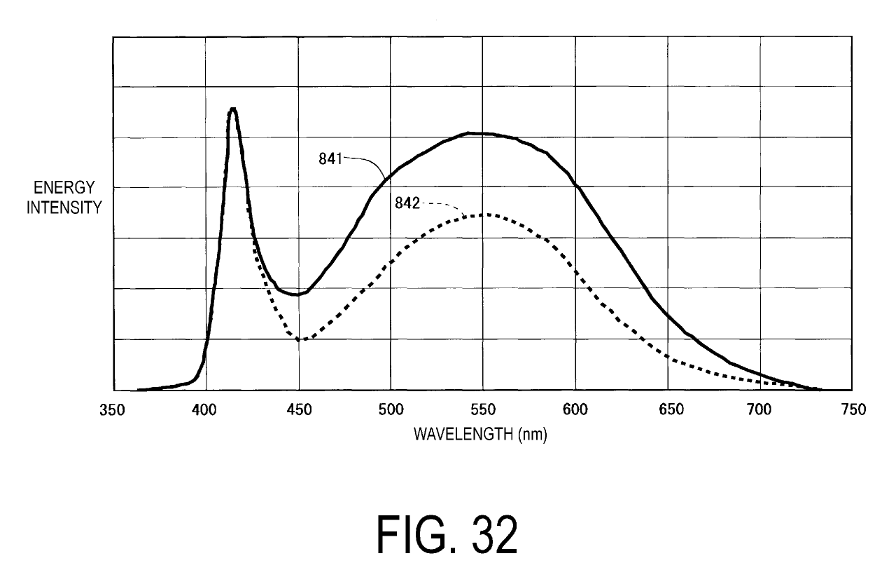

When the light emission intensity of the first white light emitter 60 (Wa) and the light emission intensity of the second white light emitter 60 (Wb) are equalized, the light emission spectrum of the light emitted from the first white light emitter 60 (Wa) is represented by a curve indicated by reference numeral 841 in FIG. 32, for example, and the light emission spectrum of the light emitted from the second white light emitter 60 (Wb) is represented by a curve indicated by reference numeral 842 in FIG. 32, for example.

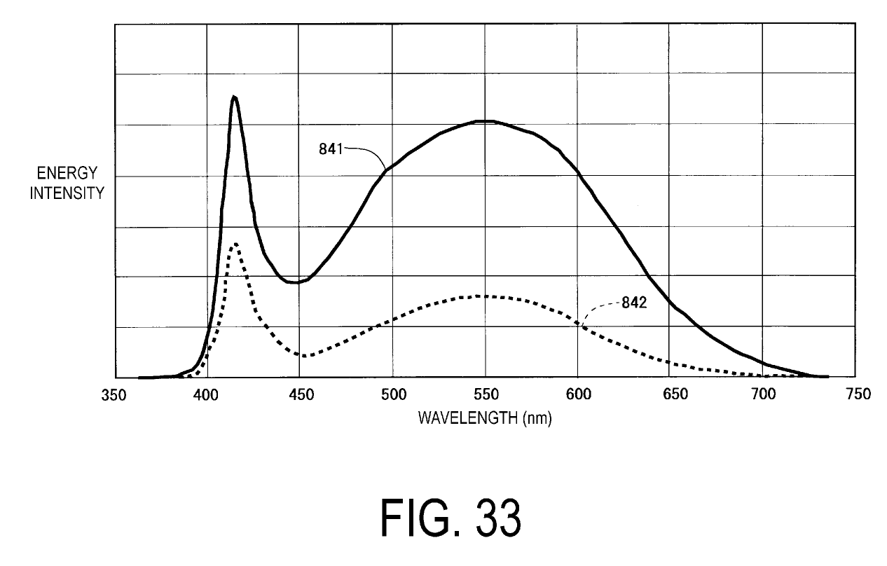

Under the above assumption, when setting the color temperature to 6500 K, the light emission intensity of the first white light emitter 60 (Wa) is relatively strengthened, and the light emission intensity of the second white light emitter 60 (Wb) is relatively weakened. As a result, the light emission spectrum 841 of the light emitted from the first white light emitter 60 (Wa) and the light emission spectrum 842 of the light emitted from the second white light emitter 60 (Wb) are as illustrated in FIG. 33. As described above, the color temperature is set to 6500 K.

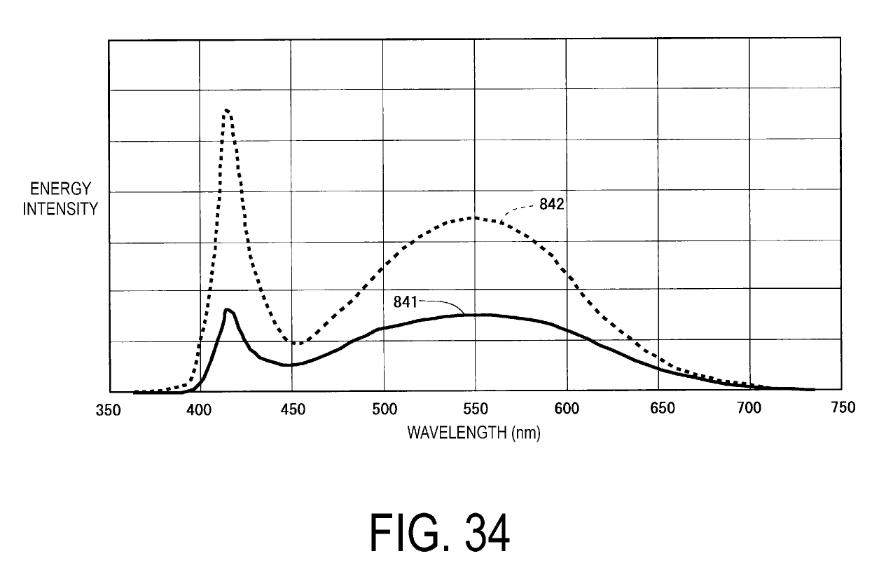

When setting the color temperature to 9300 K, the light emission intensity of the first white light emitter 60 (Wa) is relatively weakened and the light emission intensity of the second white light emitter 60 (Wb) is relatively strengthened. As a result, the light emission spectrum 841 of the light emitted from the first white light emitter 60 (Wa) and the light emission spectrum 842 of the light emitted from the second white light emitter 60 (Wb) are as illustrated in FIG. 34. As described above, the color temperature is set to 9300 K.

### 3.3 Effects

In the present embodiment, the light source constituting the backlight device 600 includes a first white light emitter 60 (Wa) having a structure in which the blue LED element 6 (B) is covered with a relatively large amount of the yellow phosphor 7 (Y) and a second white light emitter 60 (Wb) having a structure in which the blue LED element 6 (B) is covered with a relatively small amount of the yellow phosphor 7 (Y) (see FIG. 29). In this manner, the light source is composed of the two kinds of light emitters 60. In addition, the two kinds of light emitters 60 are configured so that the light emission intensities are independently controlled. As a result, since the luminance of light of the two colors can be independently controlled, it is possible to adjust and change the color temperature. The two kinds of light emitters 60 include LED elements (LED chip) of the same kind as the light emitting elements, and also contain phosphors of the same kind as wavelength conversion elements. Therefore, the combined light of light emitted from the two kinds of light emitters 60 is two lights combined having the same peak wavelength. Therefore, regardless of how the light emission intensities of the two kinds of light emitters 60 are controlled, the color purity does not decrease. Also, as in the first embodiment, the light source does not include a red LED element. As described above, in the present embodiment, similar to the first embodiment, realization of a highly reliable backlight device capable of adjusting and changing the color temperature without lowering the color purity is realized. Further, like the first embodiment, effects of lower power consumption and lower costs can be obtained.

### 3.4 Modified Example

Hereinafter, a modified example of the third embodiment will be described.

### 3.4.1 Arrangement of Light Sources

In the third embodiment, the light source on the LED substrate 62 is arranged as illustrated in FIG. 30. However, the present invention is not limited thereto. A modified example relating to the arrangement of the light sources on the LED substrate 62 will be described below.

### 3.4.1.1 First Modified Example

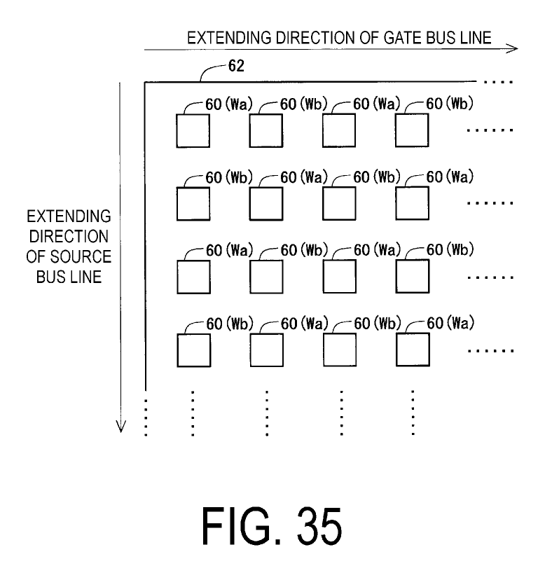

FIG. 35 is a diagram illustrating the arrangement of the light sources in the first modified example of the third embodiment. In the first row, the light emitters 60 are arranged at regular intervals in the order of “the first white light emitter 60 (Wa), the second white light emitter 60 (Wb), the first white light emitter 60 (Wa), and the second white light emitter 60 (Wb).” In the second row, the light emitters 60 are arranged at regular intervals in the order of “the second white light emitter 60 (Wb), the first white light emitter 60 (Wa), the second white light emitter 60 (Wb), and the first white light emitter 60 (Wa).” The above configuration is repeated in the extending direction of the gate bus line GL and the extending direction of the source bus line SL.

### 3.4.1.2 Second Modified Example

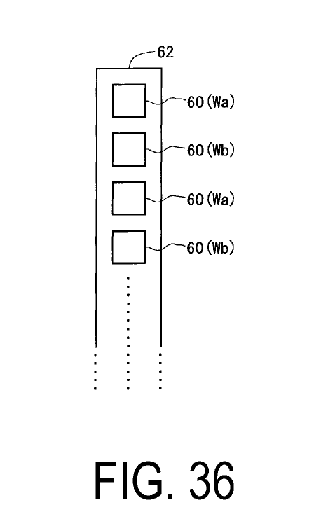

FIG. 36 is a diagram illustrating the arrangement of the light sources in the second modified example of the third embodiment. The configuration according to the present modified example is adopted when the backlight device is an edge light type. As illustrated in FIG. 36, in this modified example, a plurality of light emitters 60 are arranged at regular intervals in one row. More specifically, the plurality of light emitters 60 are arranged in one row and repeat in the order of “the first white light emitter 60 (Ma), the second white light emitter 60 (Mb), the first white light emitter 60 (Ma), and the second white light emitter 60 (Mb).”

### 3.4.2 Light Source Configuration

In the third embodiment, as illustrated in FIG. 29, the light source mounted on the LED substrate 62 is composed of a first white light emitter 60 (Wa) having a structure in which the blue LED element 6 (B) is covered with a relatively large amount of the yellow phosphor 7 (Y) and a second white light emitter 60 (Wb) having a structure in which the blue LED element 6 (B) is covered with a relatively small amount of the yellow phosphor 7 (Y). However, the present invention is not limited thereto. A modified example of the configuration of the light source mounted on the LED substrate 62 will be described below.

### 3.4.2.1 Third Modified Example

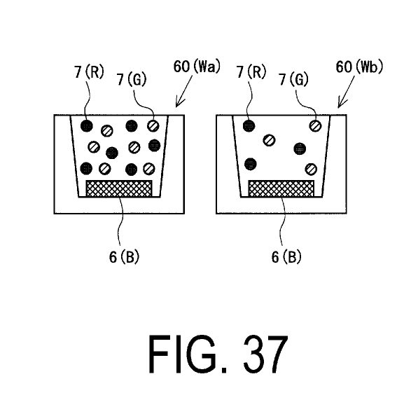

FIG. 37 is a diagram illustrating a configuration of a light source mounted on the LED substrate 62 in a third modified example of the third embodiment. As illustrated in FIG. 37, in this modified example, the light source is composed of a first white light emitter 60 (Wa) having a structure in which the blue LED element 6 (B) is covered with a relatively large amount of the red phosphor 7 (R) and a relatively large amount of the green phosphor 7 (G), and a second white light emitter 60 (Wb) having a structure in which the blue LED element 6 (B) is covered with a relatively small amount of the red phosphor 7 (R) and a relatively small amount of the green phosphor 7 (G). The first white light emitter 60 (Wa) and the second white light emitter 60 (Wb) are first type light emitters. In this manner, in this modified example, the red phosphor 7 (R) and the green phosphor 7 (G) are used instead of the yellow phosphor 7 (Y) in the third embodiment.

Blue light is emitted from the blue LED element 6 (B). Red light is emitted from the red phosphor 7 (R), and green light is emitted from the green phosphor 7 (G). The red phosphor 7 (R) and the green phosphor 7 (G) are excited by light emitted from the blue LED element 6 (B) to emit light. That is, the red phosphor 7 (R) functions as a wavelength conversion element that converts the wavelength of blue light into the wavelength of red light and the green phosphor 7 (G) functions as a wavelength conversion element that converts the wavelength of blue light into the wavelength of green light.

Since the first white light emitter 60 (Wa) contains a relatively large amount of the red phosphor 7 (R) and a relatively large amount of the green phosphor 7 (G), the first white light emitter 60 (Wa) emits a yellowish white light. Since the second white light emitter 60 (Wb) contains a relatively small amount of the red phosphor 7 (R) and a relatively small amount of the green phosphor 7 (G), the second white light emitter 60 (Wb) emits a bluish white light. As a result of combining yellowish white light and bluish white light, white light is irradiated on the liquid crystal panel 400.

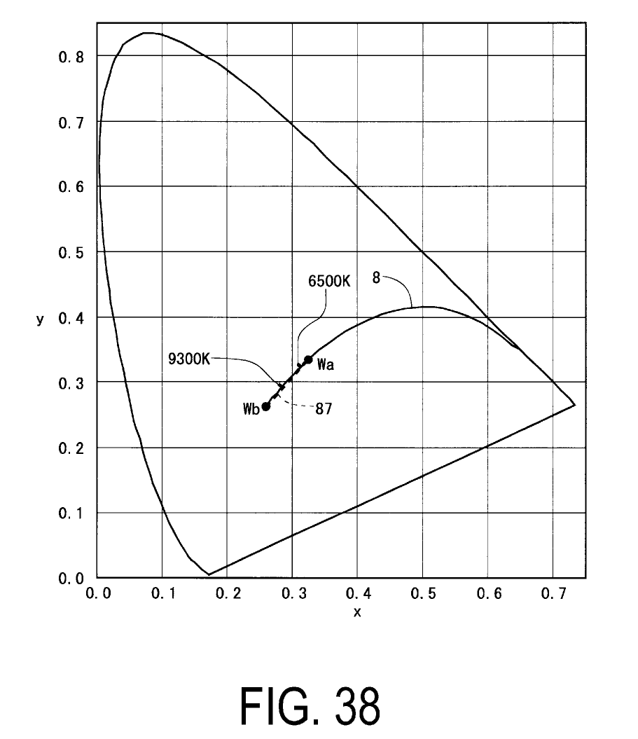

Next, how color temperature is switched in this modified example will be described. Here too, an example in which the color temperature is switched between 6500 K and 9300 K will be described. Also in this modified example, the light emission intensity of the first white light emitter 60 (Wa) and the light emission intensity of the second white light emitter 60 (Wb) are independently controlled by the backlight controller 500. That is, the luminance of the two colors of yellowish white and bluish white is independently controlled. Accordingly, on the xy chromaticity diagram, chromaticity coordinates on the line segment 87 connecting chromaticity coordinates (chromaticity coordinates of yellowish white) Wa for the first white light emitter 60 (Wa) and chromaticity coordinates (bluish white chromaticity coordinates) Wb for the second white light emitter 60 (Wb) can be selected as a white point (see FIG. 38). The chromaticity coordinates Wa for the first white light emitter 60 (Wa) and the chromaticity coordinates Wb for the second white light emitter 60 (Wb) are preferably chromaticity coordinates on a straight line passing through chromaticity coordinates corresponding to a color temperature of 6500 K and chromaticity coordinates corresponding to a color temperature of 9300 K. In the example illustrated in FIG. 38, the chromaticity coordinates Wa for the first white light emitter 60 (Wa) is (0.32, 0.337) and the chromaticity coordinates Wb for the second white light emitter 60 (Wb) is (0.25, 0.26).

When setting the color temperature to 6500 K, the light emission intensity of the first white light emitter 60 (Wa) is relatively strengthened and the light emission intensity of the second white light emitter 60 (Wb) is relatively weakened. On the other hand, when setting the color temperature to 9300 K, the light emission intensity of the first white light emitter 60 (Wa) is relatively weakened and the light emission intensity of the second white light emitter 60 (Wb) is relatively strengthened. In this way, color temperature is adjusted and changed in the same manner as in the third embodiment.

In the third embodiment, one type of phosphor (yellow phosphor 7 (Y)) is contained in the first white light emitter 60 (Wa) and the second white light emitter 60 (Wb). On the other hand, in this modified example, two kinds of phosphors (a red phosphor 7 (R) and a green phosphor 7 (G) are included in the first white light emitter 60 (Wa) and the second white light emitter 60 (Wb). Therefore, by adjusting the amounts of the two kinds of phosphors, the chromaticity coordinates Wa, Wb of each of the first white light emitter 60 (Wa) and the second white light emitter 60 (Wb) can be precisely controlled. That is, the chromaticity of the light emitted from each of the first white light emitter 60 (Wa) and the second white light emitter 60 (Wb) can be more precisely controlled. Therefore, as compared with the third embodiment, it is possible to more precisely adjust and change the color temperature.

### 4. Others

In each of the above embodiments and modified examples, examples in which an LED element (light emitting diode element) is used as a light emitting element in the light emitting body 60 have been described, but the present invention is not limited thereto. A laser diode element can also be used as the light emitting element. For example, in the configuration of the first embodiment, a laser diode element emitting blue light may be used instead of the blue LED element 6 (B).

In each of the above embodiments and modified examples, examples in which a phosphor is used as a wavelength conversion element in the light emitter 60 have been described, but the present invention is not limited thereto. Quantum dots can also be used as wavelength conversion elements. For example, in the configuration of the first embodiment, a quantum dot that converts a part of the light emitted from the blue LED element 6 (B) to the red spectrum may be used instead of the red phosphor 7 (R).

### REFERENCE SIGNS LIST

6 (R) Red LED element
6 (G) Green LED element
6 (B) Blue LED element
7 (R) Red phosphor
7 (G) Green phosphor
7 (Y) Yellow phosphor
8 Blackbody locus
60 Light emitter
60 (C1), 60 (C2) First cyan light emitter, second cyan light emitter
60 (M1), 60 (M2) First magenta light emitter, second magenta light emitter
60 (Y1), 60 (Y2) First yellow light emitter, second yellow light emitter
60 (R) Red light emitter
60 (G) Green light emitter
60 (B) Blue light emitter
60 (W1), 60 (W2), 60 (W3) First white light emitter, second white light emitter, third white light emitter
60 (Wa), 60 (Wb) First white light emitter, second white light emitter
62 LED substrate
200 Gate driver (scan signal line driving circuit)
300 Source driver (video signal line driving circuit)
400 Liquid crystal panel
410 Display unit
500 Backlight control unit
600 Backlight device

1. A backlight device using a first type light emitter as a light source composed of a light emitting element and a wavelength conversion element for converting a wavelength of light emitted from the light emitting element, the backlight device comprising:
a plurality of kinds of light emitters including at least two kinds of first type light emitters having the same kind of light emitting elements and having the same kind of wavelength conversion elements, wherein
the two or more kinds of first type light emitters emit lights having mutually different chromaticities and the plurality of kinds of light emitters are configured so that the light emission intensity of the light emitting element included in each light emitter is controlled independently for each kind of light emitter.

2. The backlight device according to claim 1, wherein the plurality of kinds of light emitters are three kinds of light emitters.

3. The backlight device according to claim 2, wherein
a second type light emitter having only a light emitting element is further used as a light source, and
the three kinds of light emitters are composed of two kinds of first type light emitters and one kind of second type light emitters.

4. The backlight device according to claim 3, wherein the amount of wavelength conversion element included in a first type light emitter of the two types is adjusted so that chromaticity coordinates corresponding to a target color temperature on an xy chromaticity diagram are within the range of a triangle connecting chromaticity coordinates of light emitted from each of the three kinds of light emitters.

5. The backlight device according to claim 3, wherein the amount of wavelength conversion element included in the two kinds of first type light emitters is adjusted so that chromaticity coordinates on a black body locus corresponding to a color temperature ranging from 4000 K to 14000 K on an xy chromaticity diagram are within a range of a triangle connecting chromaticity coordinates of light emitted from each of the three kinds of light emitters.

6. The backlight device according to claim 3, wherein the three kinds of light emitters comprise:
a first magenta light emitter including a blue light emitting diode element as a light emitting element, and a relatively large amount of red phosphor as a wavelength converting element;
a second magenta light emitter including a blue light emitting diode element as a light emitting element, and a relatively small amount of red phosphor as a wavelength conversion element; and
a green light emitter having a green light emitting diode element as a light emitting element.

7. The backlight device according to claim 2, wherein the three kinds of light emitters are all first type light emitters.

8. The backlight device according to claim 7, wherein on an xy chromaticity diagram, the amount of wavelength conversion elements included in the three types of light emitters is adjusted so that chromaticity coordinates corresponding to a target color temperature are within the range of a triangle connecting chromaticity coordinates of light emitted from each of the three kinds of light emitters.

9. The backlight device according to claim 7, wherein the three kinds of light emitters comprise:
a first white light emitter including a blue light emitting diode element as a light emitting element, a relatively large amount of red phosphor as a wavelength conversion element, and a relatively small amount of green phosphor as a wavelength conversion element;
a second white light emitter including a blue light emitting diode element as a light emitting element, a relatively small amount of red phosphor as a wavelength conversion element, and a relatively large amount of green phosphor as a wavelength conversion element; and
a third white light emitter including a blue light emitting diode element as a light emitting element, a relatively small amount of red phosphor as a wavelength conversion element, and a relatively small amount of green phosphor as a wavelength conversion element.

10. The backlight device according to claim 1, wherein the plurality of kinds of light emitters are two kinds of first type light emitters and the amount of wavelength converting elements included in the two kinds of first type light emitters is adjusted so that chromaticity coordinates corresponding to a target color temperature on an xy chromaticity diagram are positioned on a line segment connecting chromaticity coordinates of light emitted from each of the two kinds of first type light emitters.

11. The backlight device according to claim 1, wherein the plurality of kinds of light emitters are two kinds of first type light emitters, and comprise:
a first white light emitter including a blue light emitting diode element as a light emitting element, and a relatively large amount of yellow phosphor as a wavelength conversion element; and
a second white light emitting including a blue light emitting diode element as a light emitting element, and a relatively small amount of yellow phosphor as a wavelength conversion element.

12. The backlight device according to claim 1, wherein the plurality of kinds of light emitters are two kinds of first type light emitters, and comprise:
a first white light emitter including a blue light emitting diode element as a light emitting element, a relatively large amount of red phosphor as a wavelength conversion element, and a relatively large amount of green phosphor as a wavelength conversion element; and
a second white light emitter including
a blue light emitting diode element as a light emitting element, a relatively small amount of red phosphor as a wavelength conversion element, and a relatively small amount of green phosphor as a wavelength conversion element.

13. The backlight device according to claim 1, wherein the light emitting element is a light emitting diode element or a laser diode element.

14. The backlight device according to claim 1, wherein the light emitting element is a light emitting diode element other than a red light emitting diode element.

15. The backlight device according to claim 1, wherein the wavelength conversion element is a phosphor or a quantum dot.

16. A liquid crystal display device, comprising:
a liquid crystal panel having a display unit for displaying an image;
the backlight device according to claim 1 for irradiating light on a backside of the liquid crystal panel; and
a backlight control unit for controlling light emission intensity of the plurality of kinds of light emitters for each kind of light emitter.
